(19) United States
(12) Patent Application Publication
(10) Pub. No.: US 2021/0263818 A1
(43) Pub. Date: Aug. 26, 2021

(54) PREDICTIVE COMPLIANCE TESTING FOR EARLY SCREENING

(71) Applicant: Triangle IP, Inc., Englewood, CO (US)

(72) Inventor: Thomas D. FRANKLIN, Englewood, CO (US)

(73) Assignee: Triangle IP, Inc., Englewood, CO (US)

(21) Appl. No.: 17/184,496

(22) Filed: Feb. 24, 2021

Related U.S. Application Data
(60) Provisional application No. 63/153,247, filed on Feb. 24, 2021.
(60) Provisional application No. 63/152,752, filed on Feb. 23, 2021.
(60) Provisional application No. 63/121,214, filed on Dec. 3, 2020.
(60) Provisional application No. 62/980,966, filed on Feb. 24, 2020.

(51) Int. Cl. G06F 11/273; G06N 20/00

(52) U.S. Cl. CPC G06F 11/2736; G06N 20/00

(57) ABSTRACT

A compliance testing system for generating a compliance prediction for a test target. Determinate factors and indeterminate factors associated with a current testing stage of the test target are identified. A test vector for each of the indeterminate factors is generated. A set of matching test vectors for each of the indeterminate factors is determined based on the test vector. The set of matching test vectors are determined using data extracted from at least one profile model. A cumulative factor value is determined for each of the indeterminate factors based on the set of matching test vectors. A first outcome is generated for each of the determinate factors. A second outcome is generated for each of the indeterminate factors, based on the cumulative factor value and the set of matching test vectors. A compliance prediction is generated for the test target based on the first outcome and the second outcome.

### CROSS-REFERENCE TO RELATED APPLICATIONS

This application claims benefit of and is a non-provisional of co-pending U.S. Provisional Application Ser. No. 62/980,966, filed on Feb. 24, 2020, U.S. Provisional Application Ser. No. 63/121,214 filed on Dec. 30, 2020, U.S. Provisional Application Ser. No. 63/152,752 filed on Feb. 23, 2021, and U.S. Provisional Application Ser. No. 63/153,247, filed on Feb. 24, 2021, which are all expressly incorporated by reference in their entirety for all purposes.

### BACKGROUND

This disclosure relates in general to machine learning systems and, but not by way of limitation, to a compliance prediction system amongst other things.

There has always been a huge demand for high quality semiconductors in popular consumer products like smartphones and critical applications such as space and defense. Leading semiconductor manufacturers face challenge to maintain high product yields without compromising quality and time efficiency. Quality testing ensures that only good quality semiconductor chips are assembled into a product. The quality testing provides conformance to the testing standards and confidence that the product will perform as it is designed.

However, the quality testing usually takes a long time, resulting in delay in assembly of the semiconductor chips. Test data from the manufacturing is either not available in time or includes insufficient information to make a clear determination whether the chip should be rejected. The delay due to longer testing time of the semiconductor chips and packages may cause economic loss to semiconductor manufacturing industry.

### SUMMARY

In one embodiment, the present disclosure provides a compliance testing system for predicting an outcome of a compliance testing of a test target. The compliance testing system includes at least one processor and at least one memory coupled with the at least one processor. The at least one processor and the at least one memory are configured to identify determinate factors and indeterminate factors from a set of factors associated with a current testing stage of the compliance testing system. The first factor value for each of the determinate factors is available and a second factor value for each of the indeterminate factors is unavailable for the current testing stage. A test vector for each of the indeterminate factors is generated. The test vector for each of the indeterminate factors is generated based on a set of parameters associated with a corresponding indeterminate factor. A set of matching test vectors for each of the indeterminate factors based on the test vector is determined. The set of matching test vectors are determined using data extracted from at least one profile model. A cumulative factor value for each of the indeterminate factors is generated based on the set of matching test vectors. Each matching test vector within the set of matching test vectors includes a test value, the test value is determined based on a weighted average of values of the parameters. For each of the determinate factors, a first outcome corresponding to the at least one profile model is determined. For each of the indeterminate factors using a corresponding machine learning algorithm, a second outcome is generated based on the cumulative factor value and the set of matching test vectors extracted from the at least one profile model. The at least one profile model corresponds to at least one target parameter. A compliance prediction is generated at the current testing stage of the test target for the at least one target parameter based on the first outcome and the second outcome.

In another embodiment, the present disclosure provides a method of predicting an outcome of a compliance testing of a test target. Determinate factors and indeterminate factors from a set of factors associated with a current testing stage of the compliance testing are identified. A first factor value for each of the determinate factors is available and a second factor value for each of the indeterminate factors is unavailable for the current testing stage. A test vector for each of the indeterminate factors is generated. The test vector for each of the indeterminate factors is generated based on a set of test attributes associated with a corresponding indeterminate factor. A set of matching test vectors for each of the indeterminate factors is determined based on the test vector. The set of matching test vectors are determined using data extracted from at least one profile model. A cumulative factor value for each of the indeterminate factors is determined based on the set of matching test vectors. Each matching test vector within the set of matching test vectors comprises a test value and the test value is determined based on a weighted average of values of the test attributes. For each of the determinate factors, a first outcome corresponding to the at least one profile model is determined. For each of the indeterminate factors using a corresponding machine learning algorithm, a second outcome is generated based on the cumulative factor value and the set of matching test vectors extracted from the at least one profile model. The at least one profile model corresponds to at least one target parameter. And a compliance prediction is generated at the current testing stage of the test target for the at least one target parameter based on the first outcome and the second outcome.

In yet another embodiment, the present disclosure provides a compliance test system for generating a compliance prediction for a test target. The compliance test system includes a vector generating server including a processor and memory with instructions configured to identify determinate factors and indeterminate factors from a set of factors associated with a current testing stage of the compliance test system. A first factor value for each of the determinate factors is available and a second factor value for each of the indeterminate factors is unavailable for the current testing stage. A test vector for each of the indeterminate factors is generated. The test vector for each of the indeterminate factors is generated based on a set of parameters associated with a corresponding indeterminate factor. A vector matching server including a processor and memory with instructions configured to determine a set of matching test vectors for each of the indeterminate factors based on the test vector, wherein the set of matching test vectors are determined using data extracted from at least one profile model. A vector processing server including a processor and memory with instructions configured to: determine a cumulative factor value for each of the indeterminate factors based on the set of matching test vectors. Each matching test vector within the set of matching test vectors comprises a test value, the test value is determined based on a weighted average of values of the parameters. For each of the determinate factors, a first outcome corresponding to the at least one profile model is determined. For each of the indeterminate factors is generated using a corresponding machine learning algorithm, a second outcome based on the cumulative factor value and the set of matching test vectors extracted from the at least one profile model. The at least one profile model corresponds to at least one target parameter. A prediction engine including a processor and memory with instructions configured to generate the compliance prediction at the current testing stage of the test target for the at least one target parameter based on the first outcome and the second outcome.

In one embodiment, the present disclosure provides a compliance test system for generating a compliance prediction at a preliminary stage for a test target. The compliance test system includes at least one processor and at least one memory coupled with the at least one processor. The at least one processor and the at least one memory are configured to: generate a first set of test vectors for a set of parameters of the test target and a second set of test vectors based on the test target. A first outcome for the test target based on a first overlap between the second set of test vectors and the first set of test vectors. A second outcome for the test target is determined based on a second overlap between the second set of test vectors and a third set of test vectors generated for a plurality of entities extracted from at least one profile model. A third outcome is determined, by a machine learning algorithm, for the test target. The third outcome is determined by the at least one processor configured to: execute by the machine learning algorithm, an instruction corresponding to a set of evaluation rules on the second set of test vectors to determine values for a plurality of factors, determine by the machine learning algorithm, weights for the plurality of factors, and compute the third outcome based on the values and the weights determined for the plurality of factors. Further, the compliance prediction for the test target is generated. The compliance prediction is a function of the first outcome, the second outcome, the third outcome, and at least one target parameter, the at least one target parameter is associated with an application of the test target.

In another embodiment, the present disclosure provides a method of generating a compliance prediction at a preliminary stage for a test target. A first set of test vectors for a set of parameters of the test target and a second set of test vectors based on the test target is generated. A first outcome for the test target is determined based on a first overlap between the second set of test vectors and the first set of test vectors. A second outcome for the test target is determined based on a second overlap between the second set of test vectors and a third set of test vectors generated for a plurality of entities extracted from at least one profile model. A third outcome is determined, by a machine learning algorithm, for the test target. The third outcome is determined by execution, by the machine learning algorithm, of an instruction corresponding to a set of evaluation rules on the second set of test vectors to determine values for a plurality of factors. The machine learning algorithm, determines weights for the plurality of factors, and computes the third outcome based on the values and the weights determined for the plurality of factors. The compliance prediction for the test target is generated. The compliance prediction is a function of the first outcome, the second outcome, the third outcome, and at least one target parameter. The at least one target parameter is associated with an application of the test target.

In yet another embodiment, the present disclosure provides a compliance test system for generating a compliance prediction for a test target. The compliance test system includes a vector generating server, a vector processing server, and a prediction engine. The vector generating server including a processor and memory configured to generate a first set of test vectors for a set of parameters of the test target and generate a second set of test vectors based on the test target. A vector processing server including a processor and memory with instructions configured to determine a first outcome for the test target based on a first overlap between the second set of test vectors and the first set of test vectors. A second outcome for the test target is generated based on a second overlap between the second set of test vectors and a third set of test vectors generated for a plurality of entities extracted from at least one profile model. A third outcome is generated, by a machine learning algorithm, for the test target. The determination of the third outcome includes executing, by the machine learning algorithm, an instruction corresponding to a set of evaluation rules on the second set of test vectors to determine values for a plurality of factors. The machine learning algorithm determines weights for the plurality of factors and computes the third outcome based on the values and the weights determined for the plurality of factors. A prediction engine including a processor and memory with instructions configured to generate the compliance prediction for the test target at a current testing stage. The compliance prediction is a function of the first outcome, the second outcome, the third outcome, and at least one target parameter. The at least one target parameter is associated with an application of the test target.

Further areas of applicability of the present disclosure will become apparent from the detailed description provided hereinafter. It should be understood that the detailed description and specific examples, while indicating various embodiments, are intended for purposes of illustration only and are not intended to necessarily limit the scope of the disclosure.

### BRIEF DESCRIPTION OF THE DRAWINGS

The accompanying drawings, which are included to provide a further understanding of the invention, are incorporated in and constitute a part of this specification, illustrate embodiments of the invention and together with the detailed description serve to explain the principles of the invention. No attempt is made to show structural details of the invention in more detail than may be necessary for a fundamental understanding of the invention and various ways in which it may be practiced.

FIG. 1 illustrates a compliance prediction system configured to generate prediction results for a test target, according to an embodiment of the present disclosure.

FIG. 2 illustrates a parameter segregation server configured to segregate data based on targets, according to an embodiment of the present disclosure.

FIG. 3 illustrates a factor identifying server extracting factors and associated attributes from a factor database, according to an embodiment of the present disclosure.

FIG. 4 illustrates a vector generating server comprising a factor vector generator and a test vector generator, according to an embodiment of the present disclosure.

FIGS. 5A and 5B illustrate factor vectors and test vectors, according to an exemplary embodiment of the present disclosure.

FIG. 6 illustrates a storage processing server and a storage, according to an embodiment of the present disclosure.

FIG. 7 illustrates a vector matching server comprising a factor vector matcher and a test vector matcher, according to an embodiment of the present disclosure.

FIGS. 8A and 8B illustrate a score generator comprising a test scorer and a test target scorer, according to an embodiment of the present disclosure.

FIGS. 9A and 9B illustrate a prediction engine comprising a compliance generator configured to generate a compliance metric for a secondary test target and a compliance generator configured to generate a compliance metric for a primary test target, according to an embodiment of the present disclosure.

FIG. 10 illustrates a Graphical User Interface (GUI) associated with a compliance prediction system, according to an embodiment of the present disclosure.

FIG. 11 illustrates a GUI associated with a compliance prediction system configured to render a compliance metric for a secondary test target, according to an exemplary embodiment of the present disclosure.

FIG. 12 illustrates a GUI associated with a compliance prediction system configured to render a compliance metric for a primary test target, according to an exemplary embodiment of the present disclosure.

FIGS. 13A and 13B is a flowchart of a method for generating compliance metrics for test targets, according to an embodiment of the present disclosure.

FIG. 14 is a flowchart of a method for generating a compliance metric for primary test targets, according to an embodiment of the present disclosure.

FIG. 15 is a flowchart of a method for generating a score for a primary test target, according to an embodiment of the present disclosure.

In the appended figures, similar components and/or features may have the same numerical reference label. Further, various components of the same type may be distinguished by following the reference label with a letter or by following the reference label with a dash followed by a second numerical reference label that distinguishes among the similar components and/or features. If only the first numerical reference label is used in the specification, the description is applicable to any one of the similar components and/or features having the same first numerical reference label irrespective of the suffix.

### DETAILED DESCRIPTION OF THE INVENTION

The ensuing description provides preferred exemplary embodiment(s) only, and is not intended to limit the scope, applicability or configuration of the disclosure. Rather, the ensuing description of the preferred exemplary embodiment(s) will provide those skilled in the art with an enabling description for implementing a preferred exemplary embodiment. It is understood that various changes may be made in the function and arrangement of elements without departing from the spirit and scope as set forth in the appended claims.

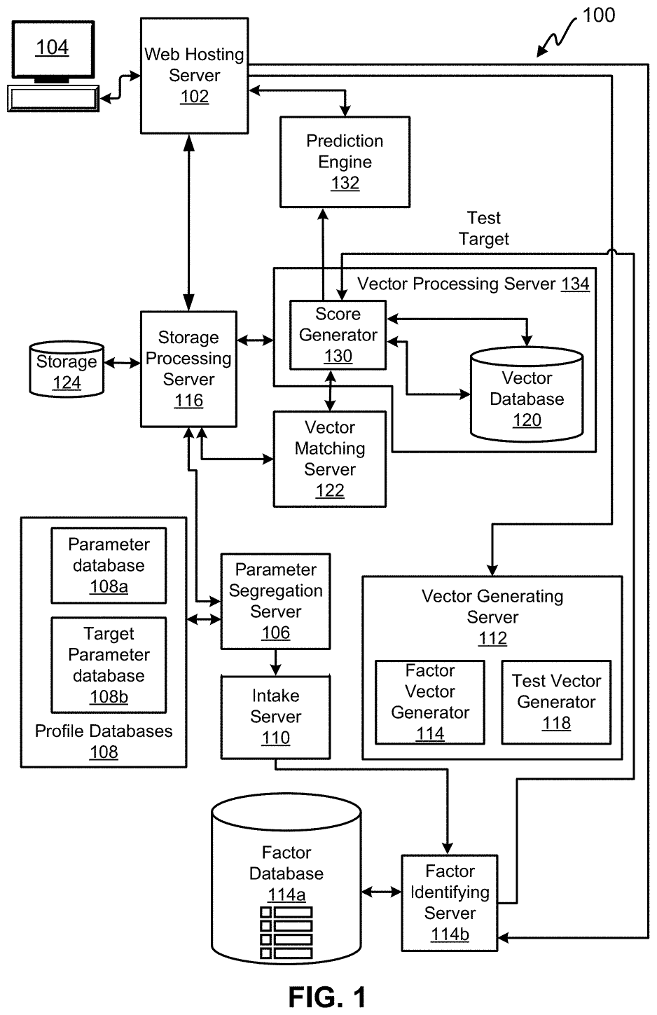

FIG. 1 illustrates a compliance prediction system 100 configured to generate prediction results for a test target, according to an embodiment of the present disclosure. The compliance prediction system 100 includes a web hosting server 102 for hosting a web page and/or GUI through which a user device 104 or many user devices 104 (not shown) may interact. The user device 104 interacts with the web hosting server 102 via the internet or via some other type of network, e.g., local area network (LAN), wide area network (WAN), cellular network, personal area network (PAN), etc. The web hosting server 102 provides a software as a service (SaaS) delivery model in which the user device 104 accesses software via a web browser in a zero footprint configuration for the user device 104, but other embodiments could use enterprise software, handheld app or computer application software. The web hosting server 102 allows the user device 104 to download and/or install a software that permits the user device 104 to use the compliance prediction system 100. A web browser in the zero footprint configuration downloads the software to work in conjunction with the software on the web hosting server 102 to provide the functionality.

The compliance prediction system 100 may include a parameter segregation server 106 that may extract various types of data from one or more of profile databases 108. The profile databases 108 also referred as profile models 108 include parameters related to a compliance test. The various types of data may include test related data. The profile databases 108, for example, may include a parameter database 108a, and a target parameter database 108b. The parameter database 108a and the target parameter database 108b may include parameter data related to the test target. Examples may include, but are not limited to input, application, and/or process parameters. The test target may be a primary test target or a secondary test target. The primary test target is the test target at a current stage of testing and the secondary test target is the test target at a final stage of testing after having passed through the current stage of testing. Data within the profile databases 108 may be identified based on tags that are assigned either manually or automatically. Example of such tags may include, but are not limited to parameter values, ranges, numbers, specifications, application areas, and the like. These tags may be used to accurately retrieve relevant data from the profile databases 108.

In an embodiment, the parameter segregation server 106 may employ one or more of a web crawler and a data miner, which may be used to retrieve parameter data from one or more of the profile databases 108. The parameter segregation server 106 may retrieve the parameter data either continuously, periodically, or when prompted by an intake server 110 within the compliance prediction system 100 to do so. For example, prior to any process being performed within the compliance prediction system 100 that uses the parameter data, the parameter segregation server 106 may be prompted to verify that the last version of the parameter data extracted from the profile databases 108 is current and that no new value of the parameter has been generated and stored in the profile databases 108. In any event, the profile databases 108 may be configured for human access to information in this embodiment so typical machine to machine transfer of information requires the parameter segregation server 106 to spoof a user account and perform data scraping. In some other embodiments, APIs and/or protocols may be used, such that, the parameter segregation server 106 is unnecessary.

After receiving the parameter data, the parameter segregation server 106 identifies a target associated with each of the parameter data either based on the associated metadata or based on the content associated with the parameter data. The parameter segregation server 106 then segregates the parameter data based on a plurality of targets and stores the parameter data in a plurality of target based databases. Examples of the plurality of targets may include, but are not limited to application areas, such as defense, satellite, electronics, space, aeronautics, and or other areas of applications. In an embodiment, the plurality of targets apply to semiconductor processing such as in this example, but other embodiments may apply the compliance prediction system 100 to patents application, race course, medical production, education system, poll results, etc.

The intake server 110 may access the parameter segregation server 106 and may extract target based parameter data from the parameter segregation server 106. In the target based parameter data, each set of the parameter data may be attributed or tagged with an associated target. By way of an example, if the target includes extraction of the parameter data that includes processing outcomes, then the parameter data may be tagged with an appropriate tag, i.e., Processing Outcomes (PO). By way of an example, if the target is extraction of the parameter data that includes testing outcomes, then the parameter data may be tagged with an appropriate tag, i.e., Testing Outcomes (TO). The intake server 110 may extract the target based parameter data either continuously, periodically, or when prompted by another component (for example, the vector generating server 112) within the compliance prediction system 100 to do so. For example, prior to any process being performed within the compliance prediction system 100 using the parameter data, the intake server 110 may be prompted to verify that the target based parameter data being used is current and that no new target based parameter data is available. In some embodiments, the parameter segregation server 106 is prompted to scrape the profile databases 108 and create new target based parameter data, while the user is interacting with the web hosting server 102.

The target based parameter data extracted by the intake server 110 may be shared with the vector generating server 112. The vector generating server 112 may generate vectors based on the target based parameter data received from the intake server 110. The vector generating server 112 may include a factor vector generator 114 that may generate one or more test vectors for a secondary test target. The secondary test target may be a target, for which a compliance prediction is required to be generated via the compliance prediction system 100. In order to generate a test vector, a set of factors and one or more test attributes associated with each of the set of factors may be considered. The mapping of the set of factors and the one or more test attributes may be stored in a factor database 114a. The one or more factors for the secondary test target may be identified based on a current testing stage of the test target. Examples of the factors may include, but are not limited to temperature, pressure, RF frequency, process duration, diode characteristics, current/voltage characteristics, leakage current parameters, metal layer characteristics, resistor and/or via characteristics, etc.

At a given stage of testing, some of these factors may be available (a first subset of factors or determinate factors). By way of an example, at the time of fabrication, the following factors may be available: process duration, temperature, pressure, RF frequency, channel depth, channel length, channel width, wafer shape, film thickness, film resistivity, inline or in-situ measurements, transistor thresholds, and/or resistance may be available. However, at the same stage of the testing, some other factors may not be available (a second subset of factors or indeterminate factors). By way of an example, the following factors may not be available: diode characteristics, drive current characteristics, gate oxide parameters, leakage current parameters, metal layer characteristics, resistor characteristics, via characteristics, clock search characteristics, diode characteristics, scan logic voltage, static IDD, IDDQ, VDD min, power supply open short characteristics, and/or ring oscillator frequency may be unavailable. Similarly, packaging parameters like pins, size, type, or tolerance might be unavailable before the test target is assembled into a package. The first subset of factors and the second subset of factors may be identified by a factor identifying server 114b. Thus, in an embodiment, for the secondary test target, the factor vector generator 114 generates test vectors for the second subset of factor vectors that are the indeterminate factors. The factor vector generator 114, for the secondary test target may store the test vectors in a vector database 120.

In a manner similar to that of the secondary test target, the factor vector generator 114 may generate the test vectors for the target based parameter data received from the intake server 110. In an embodiment, the target based parameter data may only include data for packaged test targets as stored in the parameter database 108a. Including data only for the packaged test targets ensures that values for most of the factors that are associated with test targets are already available. Thus, in this case, for the target based parameter data, only the first subset of factors may be identified, since they are available.

In an embodiment, the test vectors that are generated based on target based parameter data retrieved from the parameter database 108a may be categorized as parameter test vectors and test vectors that are generated based on target based parameter data retrieved from the target parameter database 108b are categorized as target test vectors. Each of the test vectors and the target test vectors may then be stored in a storage 124, via a storage processing server 116. The test vectors include the parameter test vectors and the target test vectors retrieved from the parameter database 108a and the target parameter database 108b, respectively. The test vectors include target parameters, and the historical values of the target parameters associated with similar test targets processed under same operating conditions and specifications by the same company.

The vector generating server 112 may further include a test vector generator 118, which may generate a plurality of test vectors based on the target based parameter data. In an embodiment, each vector from the plurality of test vectors may correspond to a test target as stored in the parameter database 108a and the target parameter database 108b. Each of the plurality of test vectors may be data structures that include one or more nodes with defined spacing between them. Nodes may correspond to test events, such as pre-fabrication, fabrication, packaging etc. Each of the test vectors may additionally be associated with one or more tags.

The test vector generator 118 may also generate test vectors for an input target for example, a primary test target. The test vectors may be generated for the primary test target in order to determine compliance results of testing the primary test target after fabrication. Predicting compliance or acceptance test results for the test target becomes very important when testing the targets is quite time consuming and a costly affair. The prediction may enable identification and subsequent resolution of any issues present in the primary test target and/or the secondary test target. This may not only help in improving quality of a semiconductor chip, but may also help in reducing future costs that may have to be incurred while performing time consuming tests. The test vector generator 118 may save the test vectors generated for the primary test target in the vector database 120.

The vector database 120 is a part of a vector processing server 134. The vector database 120 may be accessed by a vector matching server 122, which may also be communicatively coupled to the storage processor server 116. The vector matching server 122 may extract the second subset of factor vectors generated for the secondary test target from the vector database 120 and may compare these with test vectors stored by the storage processing server 116 to identify matching test vectors. In a similar manner, the vector matching server 122 may extract test vectors generated for the primary test target from the vector database 120 and may compare these with test vectors stored by the storage processing server 116 to identify matching test vectors.

The vector processing server 134 includes a score generator 130 and the vector database 120. The vector processing server 134 processes the test vectors to generate one or more scores or outcomes. With regards to the test target, once matching test vectors are identified, the score generator 130 extracts the matching test vectors from the vector matching server 122 and determines a first score and a second score for the secondary test target. The score generator 130 may also determine a first outcome and a second outcome for the secondary test target instead of the first score and the second score, respectively. The first and the second outcome may be a ratio, percentage, or a probability value. The first score is computed for each of the first subset of factors for the secondary test target. The first score is determined using the target parameter based data and may thus vary based on an end target parameter identified by a user. The second score is generated for each of the second subset of factors extracted for the secondary test target. The second score may be based on a cumulative factor value and the matching test vectors. The cumulative factor value may be separately determined for each of the second subset of factors and may be based on the matching test vectors. It may be noted that each matching test vector within the matching test vectors includes a factor value. Since the matching test vectors are derived from the target based parameter data, the second score may also vary based on the end target parameter identified by the user. For each factor in the second subset of factors, an associated machine learning algorithm may be used to generate a respective second score. The machine learning algorithm, for example, may be a deep learning network or a neural network. The associated machine learning algorithm, for a given factor, may thus be accordingly trained.

In a similar manner, with regards to the primary test target, once matching test vectors are identified, the score generator 130 extracts the matching test vectors from the vector matching server 122 and determines a first score, a second score, and a third score for the primary test target. The first score is determined for the primary test target based on a first overlap percentage between a first set of test vectors and a second set of test vectors. The first set of test vectors may be generated from standard testing parameters associated with the primary test target and the second set of vectors may be generated from actual testing parameters of the primary test target. The second score may be determined for the primary test target based on a second overlap percentage between the second set of vectors and a third set of vectors. The third set of vectors may be generated for a plurality of test targets that are extracted from one or more of the profile databases 108. The plurality of test targets may be a part of the target based parameter data extracted from the parameter segregation server 106. The third score may be determined by a machine learning algorithm. The machine learning algorithm, for example, may be a deep learning network or a neural network. In order to determine the third score, the machine learning algorithm may first execute instructions on the second set of test vectors and a plurality of test parameters of the primary test target to determine values for a plurality of factors. The instructions may be associated with a set of evaluation rules. Evaluation rules, for example, may be compliance of the primary test target with various process and/or legal standards or requirements. The machine learning algorithm may also determine weights for the plurality of factors and may then compute the third score based on the values and the weights determined for the plurality of factors.

The score generator 130 then shares the first and the second scores determined for the secondary test target with a prediction engine 132. The prediction engine 132 generates a compliance metric for the secondary test target at the current testing stage. As the first and second scores are determined based on processing of the target based parameter data, the compliance metric may be generated for one or more target parameters. The compliance metric is a function of a set of scores associated with the one more targets. In other words, each target may have an associated set of scores. By way of an example, if the target parameter is space research, the set of scores may include scores determined for the following factors “resistance to high temperature,” and “high pressure.” Further, the set of scores may be determined based on the second score determined for each of the second subset of factors and the first score determined for each of the first subset of factors. In a similar manner, for the primary test target, the prediction engine 130 shares the first, second, and third scores determined for the primary test target with the prediction engine 132. The prediction engine 132 may then generate a compliance metric for the primary test target, such that, the compliance metric is a function of each of the first score, the second score, the third score, and one or more target parameters identified by the user. The prediction engine 132, via the web hosting server 102, may then render the compliance metric on an interactive Graphical User Interface (GUI) displayed on the user device 104. The user, via the GUI, may interact with the compliance metric in order to modify the content therein.

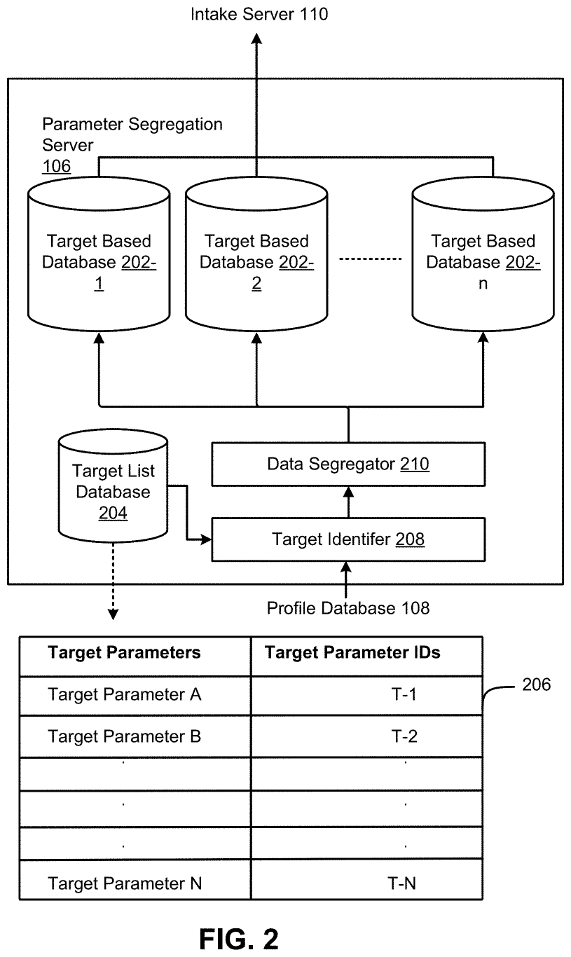

FIG. 2 illustrates the parameter segregation server 106 configured to segregate data based on targets, according to an embodiment of the present disclosure. The parameter segregation server 106 includes a plurality of target based databases 202 (i.e., target based databases 202-1 to 202-n). The number of target based databases 202 may depend on the various targets based on which the compliance metric is required to be generated for the primary test target or the secondary test target. In an embodiment, the plurality of target based databases 202 may be replaced by a single target based database, which may be used to store data segregated based on various targets. Examples of the targets may include, but are not limited to application areas, such as defense, satellite, electronics, space, aeronautics, and or other areas of applications. A list of such target parameters may be stored in a target list database 204, which may be updated periodically with one or more new targets and/or target parameters that may have evolved based on current trends and practices in the field of semiconductors. Alternatively, or additionally, the target list database 204 may be updated as and when a new target is identified. By way of an example, one of the current trends, especially, in the field of semiconductors is Nanoelectronics circuits.

In an embodiment, a target may further be divided into secondary-target parameters, each of which may further be divided into tertiary-target parameters and so on. In this embodiment, such hierarchical mapping of targets parameters may be stored in the target list database 204. By way of an example, the main target may be space application, which may further be divided into two secondary-target parameters, i.e., manage high power levels and ability to operate at high temperatures and switching frequencies. The list of target parameters stored in the target list database 204 may be displayed to a user via the user device 104, when the user initiates the process of determining compliance metric for the primary test target and/or the secondary test target. When the target parameters stored in the target list database 204 are hierarchical, such hierarchical mapping is displayed to the user, such that the user may select an intended target parameter at a granular level. Various graphical techniques for displaying the list of target parameters to the user may be employed.

The target list database 204 may further include one or more target parameter Identifiers (IDs) associated with the target parameters, such that, each target parameter may be mapped to a specific target parameter ID. This is depicted by a table 206 as shown in FIG. 2. By way of an example, the target parameter of space heat management may be mapped to the target ID ‘O-1’ and the target parameter of frequency in microchips may be mapped to the target parameter ID ‘O-2.’

The target segregating server 106 may further include a target identifier 208 that may be communicatively coupled to the target list database 204. The list of targets in the target list database 204 may be used as a guide by the target identifier 208 to identify relevant targets for the test targets extracted from the profile databases 108. As discussed earlier, the parameter data extracted from the profile databases 108 may include metadata or tags. Examples of these tags and/or metadata may include, but are not limited to time to parameter values, ranges, numbers, specifications, application areas etc.

Based on these tags and/or metadata, the target identifier 208 may identify that a specific parameter data received from one of the profile databases 108 is associated with one of the targets from the list of the targets stored in the target list database 204. Accordingly, the target identifier 208 may assign a relevant target parameter ID to that parameter data. In continuation of the example above, when the target identifier 208 determines that a given parameter data indicates temperature, the target identifier 208 may assign the target parameter ID ‘O-1’ to the given parameter data. In a similar manner, the target identifier 208 may assign and subsequently append target parameter IDs to multiple parameter data as received from the profile databases 108. In an embodiment, the target identifier 208 may assign more than one target parameter IDs to a specific parameter data. The target identifier 208 may then share the parameter data (appended with respective target parameter IDs) with a data segregator 210.

The data segregator 210 may then segregate and store the parameter data in the plurality of target based databases 202, based on the appended target parameter IDs. In an embodiment, each of the plurality of the target based databases 202 may be mapped to the target parameter ID. By way of an example, the target based database 202-1 may be dedicated for the target parameter ID ‘O-1,’ the target based database 202-2 may be dedicated for the target parameter ID ‘O-2,’ and the target based database 202-n may be dedicated for the target parameter ID ‘O-n.’ Thus, for example, the data segregator 210 may store each parameter data appended with the target parameter ID ‘O-1’ in the target based database 202-1 and so on. When a given parameter data is appended with two or more target parameter IDs, the data segregator 210 may store the parameter data in two or more target based databases 202 mapped to two or more target parameter IDs.

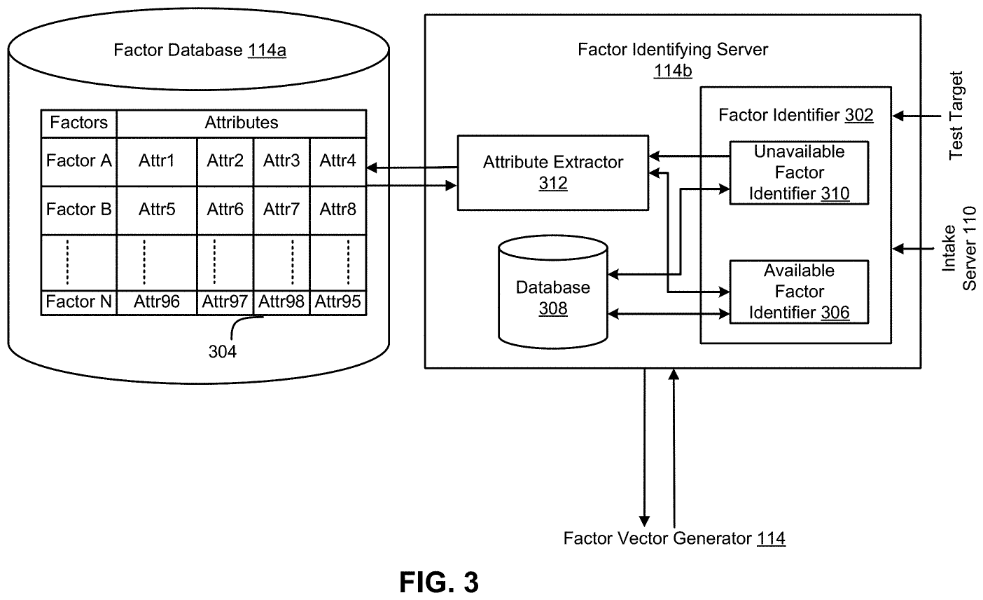

FIG. 3 illustrates the factor identifying server 114b extracting factors and associated attributes from the factor database 114a, according to an embodiment of the present disclosure. A test target may be provided by a user through a testing equipment and/or details of the test target are entered via the user device 104 to the compliance prediction system 100. With regards to the test target, a current testing stage of the test target may be identified by the factor identifying server 114b. The identification may be done based on metadata associated with the test target. The test target may be processed by the compliance prediction system 100 to extract relevant information from the profile databases 108 related to the test target. At a given stage of testing, some factors may be available or determined. By way of an example, at the time of fabrication of the test target, the following factors may be available: process duration, temperature, pressure, RF frequency, channel depth, channel length, channel width, wafer shape, film thickness, film resistivity, inline or in-situ measurements, transistor thresholds, and/or resistance may be available. However, at the same stage of testing, some other factors may not be available (a second subset of factors or indeterminate factors). By way of an example, the following factors may not be available: diode characteristics, drive current characteristics, gate oxide parameters, leakage current parameters, metal layer characteristics, resistor characteristics, via characteristics, clock search characteristics, diode characteristics, scan logic voltage, static IDD, IDDQ, VDD min, power supply open short characteristics, and/or ring oscillator frequency.

After the test target is received and relevant information has been extracted, a factor identifier 302 may identify a first subset of factors and a second subset of factors associated with the test target, from a set of factors. Each of the set of factors may have a set of attributes associated with it. A mapping between each of the set of factors and the associated set of attributes may be saved in the form of a table 304 in the factor database 114a. The table 304, for example, depicts that the ‘Factor A’ is mapped to Attributes (Attr) 1, 2, 3, and 4. By way of an example, a factor may be “temperature,” and one of the attributes mapped to this factor may be “a range associated with operating temperature,” and “a material”. By way of another example, a factor may be “frequency” and some of the attributes mapped to this factor may be “switching frequency,” “input frequency,” “clock frequency,” and/or “operating frequency.” By way of yet another example, a factor may be “noise” and some of the attributes mapped to this factor may be the “low noise,” “noise levels,” and “losses”. Thus, in crux, a given factor may have a respective set of associated attributes that may influence the value of the factor. In an embodiment, the table 304 may also include weightage associated with each attribute mapped to a given factor. These weightages may be derived based on historic parameter data related to attributes that influence value computed for a given factor. By way of an example, based on historic data, it may be determined that the factor “temperature” are largely influenced by two attributes, i.e., material and resistivity. Thus, in such cases, these attributes may be assigned much higher weightage, when compared to other relevant attributes.

In order to identify the first subset of factors, the factor identifier 302 may include an available factor identifier 306, which may identity the first subset of factors (i.e., available factors) associated with the test target. The available factor identifier 306 may identify the first subset of factors based on the information extracted from the test target. For example, if the test target has been fabricated and packaged and the ‘pins’ has been assigned, the available factor identifier 306 may be able to identify that the ‘pins’ is available based on information extracted from the test target. Alternatively, for various testing stages of the test target, a list of available and unavailable factors may be stored in a database 308. Thus, in this case, based on the current testing stage of the test target, the available factor identifier 306 may identify the first subset of factors. Thereafter, the available factor identifier 306 may share the list of first subset of factors with an attribute extractor 312. The attribute extractor 312 may further be communicatively coupled to the factor database 114a. Thus, once the attribute extractor 312 has the list of factors in the first subset of vectors, for each factor in the list, the attribute extractor 312 queries the factor database 114a and extracts associated attributes. The available factor identifier 306 may then extract the values of these associated attributes based on the metadata/tags associated with the test target or the relevant text extracted from the test target.

In a similar manner, the factor identifier 302 may include an unavailable factor identifier 310, which may identity the second subset of factors (i.e., unavailable factors) associated with the test target. In an embodiment, the factor identifier 302 may perform functionalities of both the unavailable factor identifier 310 and the available factor identifier 306, thereby eliminating the need of two separate identifiers.

Once the second subset of factors have been identified, the unavailable factor identifier 310 shares the second subset of factors with an attribute extractor 312. The attribute extractor 312 is communicatively coupled to the factor database 114a. Thus, once the attribute extractor 312 has the list of factors in the second subset of vectors, for each factor in the list, the attribute extractor 312 queries the factor database 114a and extracts associated attributes. Now, the factor identifying server 114b has information regarding the first subset of factors and values of the associated attributes, the second subset of factors, and attributes associated with each of the second subset of factors.

The factor identifying server 114b then shares information regarding the first subset of factors and values of the associated attributes with the score generator 130. Additionally, or alternatively, the factor identifying server 114b shares information regarding the second subset of factors and attributes associated with each of the second subset of factors with the factor vector generator 114, which then generates a factor vector for each of the second subset of factors, based on the associated attributes.

The factor identifying server 114b may also receive the target based parameter data from the intake server 110. In this case, the factor identifying server 114b may only identify the first subset of factors for each parameter data in the target based parameter data. In most cases, especially when the target based parameter data corresponds to the secondary test target, the first subset of factors may be equal to the set of factors. In other words, each of the set of factors may be available for such target based parameter data. In this case, the factor identifying server 114b may additionally identify values of the mapped attributes for each of the first subset of factors, since these values may already be available. The factor identifying server 114b may then share the first subset of factors of the target based parameter data along with values of the associated attributes with the factor vector generator 114.

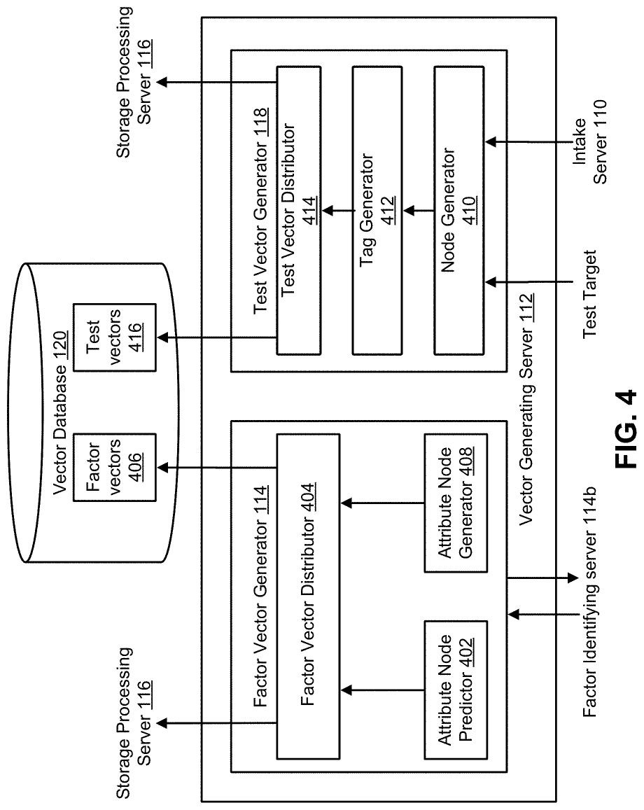

FIG. 4 illustrates the vector generating server 112 that includes the factor vector generator 114 and the test vector generator 118, according to an embodiment of the present disclosure. As discussed before, the factor vector generator 114 is relevant for the test target and generates factor vectors based on inputs received from the factor identifying server 114b. The inputs, as discussed before, may be associated with two different sources. One or more of the inputs may be associated with the test target, while other inputs may correspond to the target based parameter data as received from the intake server 110.

Further, as discussed before, the input data that is associated with the test target may include information regarding the second subset of factors determined for the test target and attributes associated with each of the second subset of factors. Since values of each of the attributes associated with the second subset of factors are not available, the second subset factors along with the associated attributes is provided to an attribute node predictor 402. For each factor in the second subset of factors, the attribute node predictor 402 may analyze the associated attributes and may generate one or more nodes that are to be predicted. For a given factor, each node may represent a specific attribute and a size of the that node may indicate a weightage associated with that attribute in influencing determination of a value of the factor. Based on these nodes and their respective size, factor vectors may be generated for each of the second subset of factors identified for the test target. The information as to weightage of each attribute associated with a specific factor may also be received from the factor identifying server 114b. It may be noted that the one or more nodes generated by the attribute node predictor 402 do not have any value associated with them, since these values are yet to be predicted. The attribute node predictor 402 then shares these vectors with a factor vector distributor 404 which then forwards these vectors to the vector database 120. The vector database 120 then stores these factors associated with the test target as factor vectors 406, Based on the factor vectors 406, values of each of the second subset of factors for the test target may be predicted.

The input data that is associated with the target based parameter data may include a first subset of factors of the target based parameter data along with values of the associated attributes. Since values of the attributes associated with the first subset of factors is available, the first subset factors along with the associated attributes and their values is provided to an attribute node generator 408. For each factor in the first subset of factors, the attribute node generator 408 may analyze the associated attributes and their values to generate one or more nodes. For a given factor, each node may represent a specific attribute and a size of the that node may indicate a weightage associated with that attribute in influencing determination of a value of the factor. Additionally, each node may further be appended with a respective value as obtained from the factor identifying server 114b. Based on these nodes and their respective size and values, factor vectors may be generated for each of the first subset of factors identified for the target based parameter data. It may be noted that each factor vector generated for the target based parameter data may also be assigned a target parameter ID as a tag. The target parameter ID may be derived from the target based parameter data, which has been appended with the target parameter ID, as described in FIG. 2. Thus, for a given parameter data in the target based parameter data, multiple factor vectors tagged with a target parameter ID may be generated, such that, each factor vector may represent one factor from the first subset of factors.

The attribute node generator 408 then share these factor vectors with the factor vector distributor 404, which may store these factor vectors generated based on the target based parameter data in the storage 124 via the storage processing server 116. In some embodiments, the factor vector distributor 404 may make a determination as to whether a vector is public or private. This determination may be based on whether a corresponding target based parameter data is public (e.g., has been published online) or private. A public factor vector may be stored separately from a private factor vector in the storage 124 by the storage processing server 116. In some embodiments, the factor vector distributor 404 makes the determination as to whether a factor vector is public or private by analyzing a source associated with the target based parameter data for which the factor vector was generated. In an embodiment, the target based parameter data may have that information appended thereto. It may be noted that generation and subsequent storage of the factor vectors for the target based parameter data may be independent and disconnected with generation of the factor vectors associated with the test target. Additionally, to reiterate, the factor vectors generated for the test target are stored in the vector database 120 (as the factor vectors 406), while the factor vectors generated for the target based parameter data are stored in the storage 124, via the storage processing server 116.

The test vector generator 118 is relevant for the primary test target and generates test vectors based on the input primary test target and based on the target based parameter data received from the intake server 110. The test vector generator 118 includes a node generator 410, a tag generator 412, and a test vector distributor 414. For the primary test target (for example, a wafer), the node generator 410 may identify various specification sections for the primary test target. By way of an example, the sections may include details for example, but are not limited to operating temperature, frequency, power levels, noise and/or material. The node generator 410 may generate a set of nodes for the primary test target. Each node may represent values for the sections of the primary test target.

A test vector may then be generated for the primary test target based on the set of nodes. Moreover, the set of nodes may be distributed on the vector, such that, distance between adjacent nodes may be proportional to similarity between the values represented by these adjacent nodes. Thus, for a given test vector, if the spacing between the nodes is high, that indicates the values are high in the particular testing phase of the primary test target. In other words, the variations in the values over the standard specifications during the testing phases may be included therein. High overlap may also be indicated by the number of nodes and size of these nodes. In an embodiment, if the number of nodes in a vector are more and additionally, or alternatively, size of the nodes is small, high overlap within the specification of the primary test target may be indicated. However, if the spacing between the nodes is low, that may indicate low overlap with the standard specifications.

In some embodiments, the node generator 410 may generate a second set of test vectors based on the primary test target, such that, a plurality of subset of test vectors within the second set of vectors may corresponds to a plurality of sections within the primary test target. In other words, the node generator 410 may generate one or more test vectors for each specification section of the primary test target. By way of an example, the node generator 410 may generate one or more test vectors for the specification sections of the primary test target.

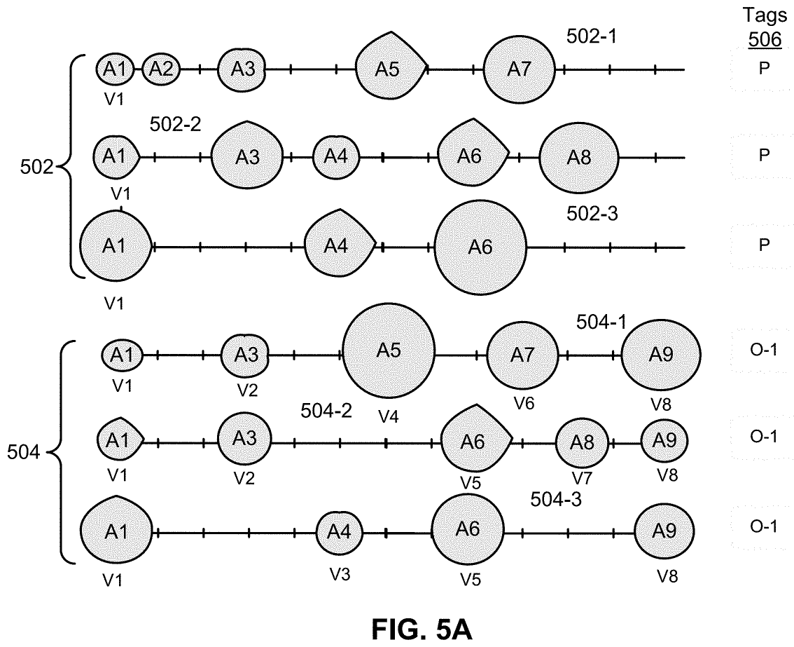

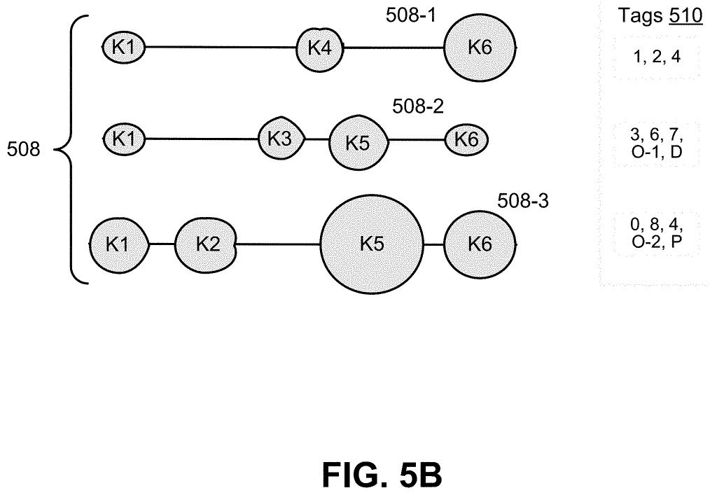

Thereafter, the tag generator 412 applies one or more tags to each test vector. A tag may indicate a characteristic or property of a test vector, and may be derived from the administrative data or from some other source. Examples of tags may include, but are not limited to parameter values, ranges, numbers, specifications, application areas, and the like. The tag generator 412 automatically generates the tags for test vectors from administrative data and/or from user input. Tags may be applied to the test vectors by the tag generator 412 or may be applied later by a user. For example, the tag generator 412 may apply the tags “temperature range”, “Model No. S45X”, and “Package ID” to a particular test vector. A user may later apply the tag “high frequency” to the same test vector. In some embodiments, a user may modify, delete, or add an existing tag. After the tag generator 412 applies tags to each test vector generated for the primary test target, the test vector distributor 414 may store the test vectors along with the tags generated for the primary test target as test vectors 416 in the vector database 120. Such exemplary test vectors are depicted and explained with reference to FIG. 5B.

In a manner similar to the primary test target, the test vector generator 118 generates test vectors for the target based parameter data received from the intake server 110. In this case, along with the tags applied or appended to the test vectors, the respective target ID may also be appended to each test vector. The test vector distributor 414 may store the test vectors generated for the target based parameter data in the storage 124, via the storage processing server 116. In some embodiments, the test vector distributor 414 may make a determination as to whether a value of the test parameters of the test vector is public or private. This determination may be based on whether a corresponding target based parameter data is public (e.g., has been published online) or private. A public test vector may be stored separately from a private test vector in the storage 124 by the storage processing server 116. In some embodiments, the test vector distributor 414 makes the determination as to whether a test vector is public or private by analyzing a source associated with target based parameter data for which the test vector was generated. In an embodiment, the target based parameter data may have that information appended thereto. By way of an example, if the source is identified as target parameter database 108b, the test vector may be identified as a target parameter test vector.

FIGS. 5A and 5B illustrate factor vectors and test vectors, according to an exemplary embodiment of the present disclosure. FIG. 5A depicts factor vectors 502 generated from a test target (analogous to the factor vectors 406) and factors vectors 504 that are generated for a parameter data within the target based parameter data. Each of the factor vectors 502 and 504 are appended with tags, which are depicted in a tag section 506. Since the factor vectors 502 are generated for a second subset of factors (that are currently unavailable) identified for the test target, each of the factor vectors are appended with a tag ‘P,’ indicating that the value of a factor associated with each of the factor vectors 502 is required to be predicted and thus values of some of the nodes representing various attributes may also need to be predicted. With respect to the factor vectors 504, they are appended with a target parameter ID as a tag. For example, the parameter data used to generate the factor vectors 504 may have been appended with the target parameter ID ‘O-1,’ which may correspond to space application. Thus, each of the factor vectors 504 may be appended with the tag ‘O-1.’ Additionally, each node in the factor vectors 504 may have an associated value. By way of an example, if a factor is “material,” the attribute “silicon” may have the value as “oxide” as both correspond to the materials of the test target.

As depicted for the factor vectors 502 and 504, nodes are placed at specific stage of testing. Only one node is depicted at a given testing stage for illustrative purpose and ease of explanation. However, multiple such nodes may be placed at the given testing stage. By way of an example, for a factor vector 502-1 (which may correspond to “wafer shape”), the node representing attribute ‘A1’ (for example, film thickness) may be available at the time of fabricating the test target and thus value of ‘A1’ is already available as ‘V1.’ Thus, at any given stage of testing of the test target, a set of attributes may already be known. Some of these attributes may also be relevant for determining values of unavailable factors (the second subset of factors). As will be explained further, values of available attribute within a factor vector for a factor that needs to be predicted, may be used to find matching factor vectors from the factor vectors that were generated from the target based parameter data (the factor vectors 504, for example.)

At the current testing stage of the test target, some of the attributes may not be available and may have to be predicted. By way of an example, for a factor vector 502-1, the node representing attribute ‘A2’ (for example, pins) may be available only at the testing stage that occurs a couple of months after fabrication of the test target probably in packaging stage, and since the test target has just been fabricated, the value of this attribute may need to be predicted.

With regards to size of the nodes representing attributes, for different factor vectors, size of node representing a given attribute may vary. By way of an example, for a factor vector 504-1, the value of attribute ‘A1’ (for example, material) is available at the time of fabricating. It may be noted that for the factor vectors 504-1 to 504-3, the size of the node representing the attribute ‘A1’ is different. This indicates that for different factors, relevance and/or weightage of the same attribute may differ substantially. In fact, a given attribute that is most relevant for a given factor may not be relevant for other factors. This is depicted by the node representing the attribute ‘A5,’ which is most prominent in the factor vector 504-1 and is not present in the factor vectors 504-2 and 504-3. For one of the factor vectors 504, for example, the factor vector 504-1, based on values of attributes for the factor vector 504-1, a factor value may be determined for the factor vector 504-1. In some embodiment, the factor value may be a weighted sum of values of the attributes in the factor vector 504-1.

In some embodiments, value of an attribute may be a vector representation of the actual attribute value. By way of an example, if actual value of the attribute “Material” is “Silicon,” it may be converted to a vector representation before being applied to a factor vector.

FIG. 5B depicts test vectors 508. A test vector 508-1 may be generated for a wafer, while a test vector 508-2 may be generated for a parameter data (derived from the parameter database 108a) and a test vector 508-3 may be generated for a parameter data (derived from the target based parameter data). Each of the test vectors 508 are appended with tags, which are depicted in a tag section 510. The numerals may represent specific codes associated with tags. The test vectors 508-2 and 508-3 may additionally be appended with target parameter-IDs and source tags. By way of an example, the test vector 508-2 may be appended with the target parameter-ID ‘O-1’ assigned to the parameter and the source tag ‘D’ indicating the parameter database 108a as the source. By way of another example, the test vector 508-3 may be appended with the target parameter-ID ‘O-2’ and the source tag ‘D’ indicating the public parameter database 108a and/or the private parameter database 108b as the source.

In each of the test vectors 508, “K’ represents a specific parameter and size of a node represent importance of that parameter for the test target. By way of an example, referring to the test vector 508-1 which is generated for the test target. The keywords ‘K6’ is the most important parameter for example, heat resistance with respect to the space applications.

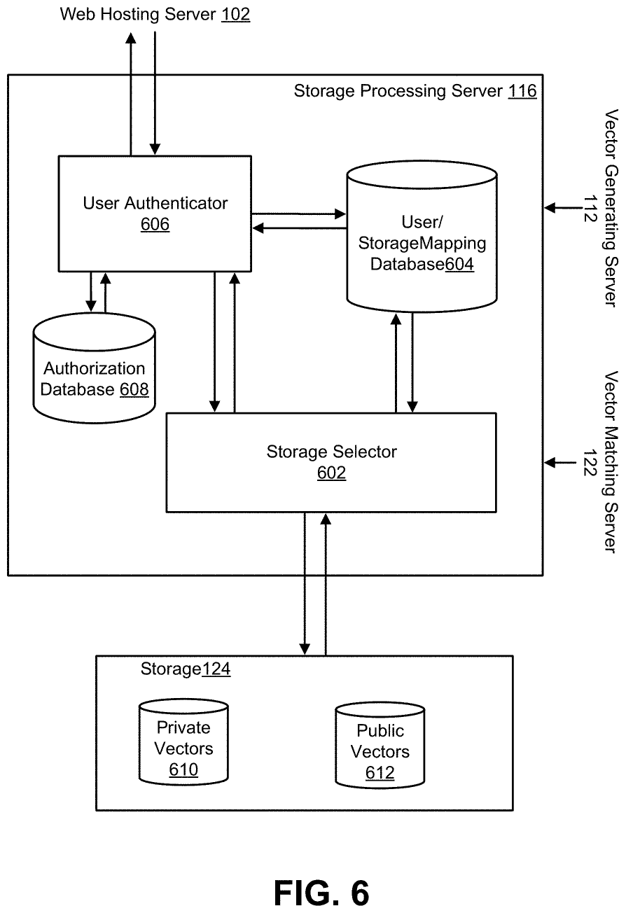

FIG. 6 illustrates the storage processing server 116 and the storage 124, according to an embodiment of the present disclosure. To determine the proper storage to route information through, a storage selector 602 accesses a user/storage mapping database 604 which includes a mapping between users and storages. For example, the user/storage mapping database 604 may indicate that a first user has access to the storage 124 only, a second user has access to a different storage (not shown in FIG. 6). By way of another example, a private vector (test vector and/or factor vector) may be sent to the storage processing server 116 and the storage selector 602. The storage selector 602 may analyze the administrative data associated with the private vector to determine that the private vector corresponds to the first user. The storage selector 602 may then access the user/storage mapping database 604 to determine which storage the first user may access. After determining that the first user has access to the storage 124, the storage selector 602 may route and store the private vector in the storage 124.

The storage processing server 116 includes a user authenticator 606 for verifying that a storage requestor has the proper authentication to access the specific storage being requested. The user authenticator 606 first determines which user is requesting access. Second, the user authenticator 606 accesses the user/storage mapping database 602 to determine whether the user has access to any of the storages (for example, the storage 124). Third, the requester is routed to the storage selector 602 for identifying and selecting the proper storage. In some embodiments, a storage requestor requests to access a specific storage, for example, the storage 124. In other embodiments, a storage requestor requests to access a non-specific storage, i.e., any available storage. For example, when a storage requestor requests to only store information in any available storage of, the storage selector 602 may identify, select, and route information to any available storage to which the user is authorized to access. The storage 124 may include various user-specific information including, but not limited to: private vectors 610 and public vectors 612 (test vectors and/or factor vectors) submitted by an authorized user.

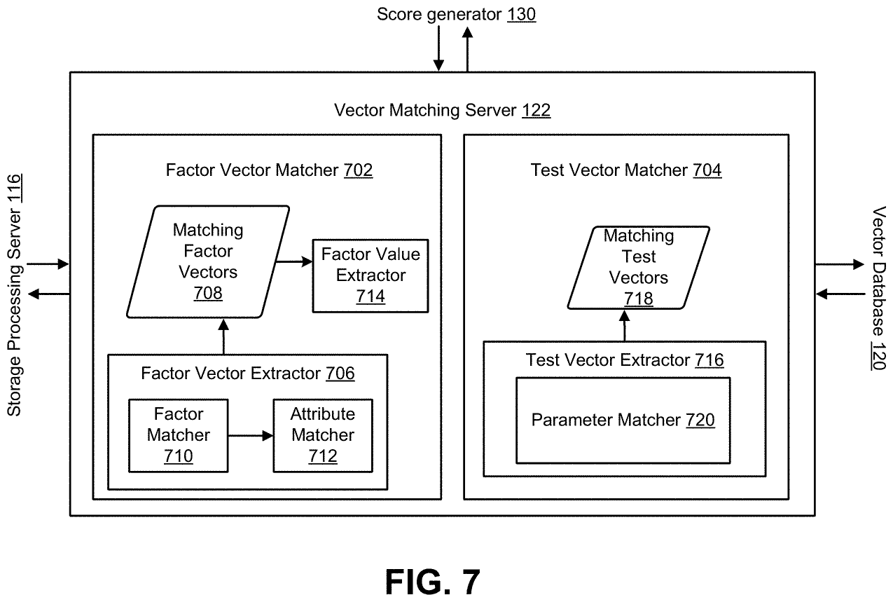

FIG. 7 illustrates the vector matching server 122 that includes a factor vector matcher 702 and a test vector matcher 704, according to an embodiment of the present disclosure. The vector matching server 122 may be communicatively coupled to the storage processing server 116 in order to extract one or more factor vectors and one or more test vectors created based on the target based parameter data. The vector matching server 122 may also be communicatively coupled to the vector database 120 in order to extract the factor vectors 406 created for the primary test target and the test vectors 416 created for the secondary test target.

The factor vector matcher 702 may include a factor vector extractor 706 that may extract and identify matching factor vectors 708. The matching factor vectors 708 are identified based on their match with the factor vectors 406. It may be noted that the factor vectors 406 may include a set of factor vectors that correspond to a second subset of factors, which were unavailable for the test target at its current stage of testing. Values for each of the second subset of factors is required to be predicted. By way of an example, at the current stage of testing, the following factors may be unavailable: “pin,” “tolerance,” or “electrode distance.” The test target may also have a first subset of factors for which values may already be available along with values of the associated attributes. In an embodiment, some of the attributes for the second subset of factors may also be available at the current testing stage.

To identify the matching factor vectors 708, the factor vector extractor 706 may include a factor matcher 710 and an attribute matcher 712. The factor matcher 710 may first extract the factor vectors 406 created for the second subset of factors for the test target from the vector database 120. The factor matcher 710 thus also has a complete list of factors in the second subset of factors, values for which are required to be predicted. Based on the list of factors obtained, the factor matcher 710 may first extract factor vectors (generated based on the target based parameter data) associated with these factors from the storage processing server 116. By way of an example, factor that needs to be predicted for the test target may be “frequency.” In this case, the factor matcher 710 may only extract those factor vectors from the storage processing server 116, which have been created for the factor of “frequency” based on the target based parameter data. In this example, 10 such factor vectors may be stored in the storage processing server 116. Thus, the factor matcher 710 may extract all these 10 factor vectors from the storage processing server 116.

The factor matcher 710 may then share details of the factor vectors 406 and initial list of the factor vectors extracted from the storage processing server 116 with the attribute matcher 712. With respect to the factor vectors 406, the details may include list of the factors corresponding to the factor vectors 406, the attributes for which the values are already available, and attributes for which values are not available at the current testing stage. By way of an example, details may include the factor “Frequency” and values of the following attributes: “Range,” “Operating temperature,” “Wafer size,” or “Resistivity.” Details may also include the following attributes, for which the values are not available at the current testing stage: “Pins,” “Tolerance,” “Tape and reel.”

With respect to the initial list of the factor vectors extracted from the storage processing server 116, the details may include list of factors and values of the attributes associated with each of the list of factors. In continuation of the example give above, for the factor vectors that correspond to the factor “Frequency,” details may include values of the following attributes: “Range,” “Operating temperature,” “Wafer size,” or “Resistivity,” “Pins,” “Tolerance,” and “Tape and reel.”

Once the attribute matcher 712 has received the details from the factor matcher 710, for each of the factor vectors 406, the attribute matcher 712 compares values of available attributes with values of attributes corresponding to the factor vectors extracted from the storage processing server 116. Based on matching values of attributes, the attribute matcher 712 identifies the matching factor vectors 708. In some embodiments, the matching factor vectors 708 are identified when their match is above a predefined threshold. The predefined threshold may correspond to matching of each of the attribute of a factor vector from the factor vectors 406, for which the value is available. Alternatively, the predefined threshold may correspond to matching of at least one attribute of a factor vector from the factor vectors 406, for which the value is available. In continuation of the example given above, since values of the following attributes “Range,” “Operating Temperature,” “Wafer size,” or “Resistivity” is available, the attribute matcher 712 compares values of these attributes with values of same attributes in the factor vectors generated for “Frequency” and extracted from the storage processing server 116. Thus, out of the 10 factor vectors extracted by the factor matcher 710, the attribute matcher 712 may identify only three factor vectors based on matching attribute values. In other words, for these three factor vectors, the “Range,” “Operating Temperature,” “Wafer size,” and/or “Resistivity may match with that of a factor vector in the in the factor vectors 406.

As discussed before, each of the matching factor vectors 708 may have a factor value associated with it, which may be determined based on a weighted average of the attribute values. The factor value extractor 714 may extract the factor values associated with each of the matching factor vector 708 and may share these factor values with the score generator 130.

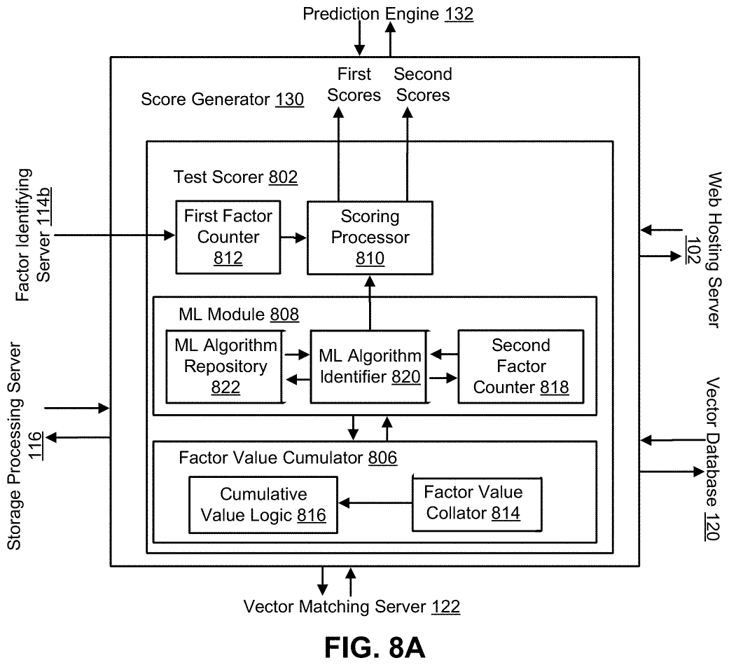

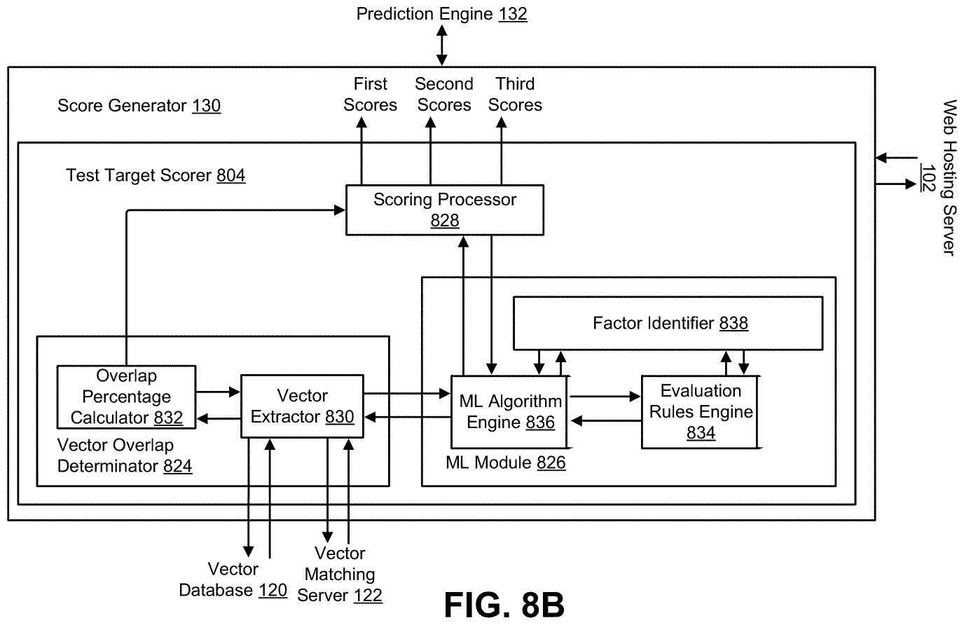

The test vector matcher 704 may include a test vector extractor 716 that may extract and identify matching test vectors 718 via the storage processing server 116. The matching test vectors 718 may be identified based on their match with the test vectors 416 stored for the primary test target in the vector database 120. To identify the matching test vectors 708, the test vector extractor 716 may include a parameter matcher 720. The parameter matcher 720 may first extract the test vectors 416 from the vector database 120 and may compare each of the test vectors 416 with the test vectors stored in the storage 124, via the storage processing server 116. Based on the comparison, the parameter matcher 720 may identify and extract the matching test vectors 718. The matching test vectors 718 may be identified, such that, similarity in each of the matching test vectors 718 when compared with one of the test vectors 416 is greater than a predefined similarity threshold. It may be noted that each of the matching test vectors 718 are appended with target parameter-ID and a source tag (i.e., ‘P’ indicating parameter data as the source or ‘D’ indicating target parameter as the source). The test vector matcher 704 then shares the matching test vectors 718 with the score generator 130, which is further explained in detail with reference to FIGS. 8A and 8B.

FIGS. 8A and 8B illustrate the score generator 130 that includes a test scorer 802 and a test target scorer 804, according to an embodiment of the present disclosure. The test scorer 802 may determine scores for a secondary test target and is depicted in FIG. 8A, while the test target scorer 804 may determine scores for a primary test target and is depicted in FIG. 8B.

The test scorer 802 may include a factor value cumulator 806, a Machine Learning (ML) module 808, a scoring processor 810, and a first factor counter 812. The factor value cumulator 806 may determine a cumulative factor value for each of the second subset of factors for the secondary test target, based on the matching factor vectors 708. To this end, the factor value cumulator 806 may include a factor value collator 814 and a cumulative value logic 816. The factor value collator 814 may collate values of the factors associated with the matching factor vectors 708 as received from the factor vector matcher 702. The factor value collator 814 may then share these factor values with the cumulative value logic 816, which may store various logics for determining the cumulative factor value for each of the second subset of factors for the secondary test target. The logics may be modified by an administrator based on current requirements or to increase accuracy of the score generator 130. In an embodiment, the cumulative factor value for one of the second subset of factors may be determined as a simple average of the factor values obtained for the matching factor vectors 708. Additionally, or alternatively, before computation of the cumulative factor value for a given factor from the second subset, the cumulative value logic 816 may segregate each of the factor values received from the factor value collator 814 based on the target parameter ID appended to the associated matching factor vectors 708. Thus, for a given factor (that is unavailable) of the secondary test target, the cumulative value logic 816 may determine multiple target specific cumulative factor values and then share the same with the ML module 808.

The ML module 808 may include a second factor counter 818, an ML algorithm identifier 820, and an ML algorithm repository 822. The second factor counter 818 may keep a record of the total number of the second subset of factors (that are unavailable) and may maintain a counter for the same. The second factor counter 818 may select a factor and may prompt the ML algorithm identifier 820 to identify an ML algorithm that has been trained to compute a second score for that factor. The ML algorithm identifier 820 may include a mapping of factors with a corresponding trained ML algorithm. Thus, in response to the prompt from the second factor counter 818, the ML algorithm identifier 820 may extract the trained ML algorithm mapped to the factor from the ML algorithm repository 822. The trained ML algorithm may be trained to determine a second score for the factor based on the one or more cumulative factor values determined for the factor, as received from the factor value cumulator 806. The ML algorithm repository 822 may include a trained ML algorithm for each factor. Once the trained ML algorithm has been identified for the factor, the ML module 808 may share the trained ML algorithm and the one or more cumulative factor values determined for the factor with the scoring processor 810. Thereafter, the process may be repeated for each factor in the second subset of the factors and the second factor counter 818 may keep on increasing its counter till all the factors in the second subset have been processed for identification of an associated trained ML algorithm.

The ML algorithm identifier 820 and the ML algorithm repository 822 may be updated as and when a new factor is identified and an ML algorithm is trained to determine a second score for the new factor. An ML algorithm, for example, may be a deep learning or neural network. Examples may include, but are not limited to Convoluted Neural Network (CNN), Recurrent Neural Network (RNN), or Long Short Term Memory (LSTM). In order to train an ML algorithm to determine a factor value for a particular factor, a dataset of factor vectors may be created for that factor and the ML algorithm may be specifically trained for that factor using this dataset. In a similar manner, a dataset of factor vector may be created for each factor. By way of an example, the factor may be “Frequency.” In this case, to create the dataset of factor vectors, test targets may be selected, such that, equal percentage of these test targets have high frequency range. Thus, the dataset would have equal representation from the test targets having varying high frequency ranges. Additionally, the test targets may be selected, such that, one or more attributes are repeated across these test targets. The attributes, for example, may be “Range,” “Operating Temperature,” “Material,” and/or “Resistivity.” Further, for a given factor, multiple factor vectors would be created for the test target, such that, for each testing stage, the dataset may include one factor vector for the test target and the factor. By way of an example, 2 main testing stages of the test target may be considered, such that, the first testing stage is fabrication, and the second testing stage is packaging of the test target. In this case, for a given factor, 10 different factor vectors would be created for the test target. In a similar manner, multiple factor vectors are created for each of the test targets that have been selected to create the dataset.

Thereafter, one by one, for a given test target, a factor vector at each testing stage, except the last testing stage is considered. For this factor vector and a given testing stage, matching factor vectors are determined from the factor vectors generated from the test targets used to create the dataset. The matching vectors are then used to determine a cumulative factor value for the given test target. The determination of cumulative factor value has already been explained. The cumulative factor value and the matching factor vectors are then fed into the ML algorithm as an input. If the ML algorithm is a neural network, multiple layers in the neural network may process the cumulative factor value and the matching factor vectors to generate a value for the factor. Since the actual value of the factor is already know, the output factor value of the ML algorithm may be compared with the actual value of the factor to determine any discrepancies. By way of an example, for a test target, the factor “temperature” is already known. Now, the factor vector generated for the test target at the stage of fabricating the test target is considered to train the ML algorithm. Thus, the output factor value of the ML algorithm in this case is compared with an actual temperature after fabrication.

The discrepancies so determined between the output factor value and the actual factor value is then fed back into the ML algorithm. The discrepancies are used by the ML algorithm for incremental learning, based on which the ML algorithm adjusts or adapts the output to minimize the discrepancies. Thereafter, the ML algorithm again generates an output factor value, which is again compared with the actual value of the factor, in order to determine discrepancies. This iterative process is carried out till discrepancies between the output factor value of the ML algorithm and the actual factor value are minimal or approach zero. Once this stage is reached, the ML algorithm is considered trained for that particular factor and the particular testing stage of a secondary test target. Thereafter, this training process is carried out iteratively for this factor at all testing stages. In a similar manner, separate datasets may be created for each factor and the associated ML algorithm may be accordingly trained for various testing stages as explained above. The ML algorithm may further be trained to generate factor values that are specific to a particular target. In this case, the dataset may have to be accordingly selected, such that target specific test targets are selected to create the dataset.

For a given factor of the secondary test target, when the scoring processor 810 has received the trained ML algorithm, cumulative factor values, and a subset of matching factor vectors (extracted from the matching factor vectors 708) relevant for the factor, the scoring processor 810 executes the trained ML algorithm using the cumulative factor value and the subset of matching vectors as input to determine a factor value for the factor. The scoring processor 810 may then determine a second score for the factor based on comparative analysis of the factor value with factor values of test targets associated with the subset of matching vectors. In an embodiment, the second score may be determined based on the percentile score of the factor value when compared with factor values associated with the subset of matching vectors. In an exemplary embodiment, if the factor value lies in the top 10 percentile, a score of ‘1’ may be assigned to the secondary test target with respect to the factor. However, if the factor value lies in the bottom 10 percentile, a score of ‘10’ may be assigned to the secondary test target. The scoring scale may be from 1 to 10, where ‘10’ is the lowest score, while ‘1’ is the highest score. In an embodiment, the scoring processor 810 may generate a target specific second score for the secondary test target. To this end, the subset of matching vectors may be selected, such that, they correspond to a specific target. Thus, the scoring processor 810 may generate multiple target specific second scores for the secondary test target. The scoring processor 810 may then share the multiple target specific second scores with the prediction engine 132.

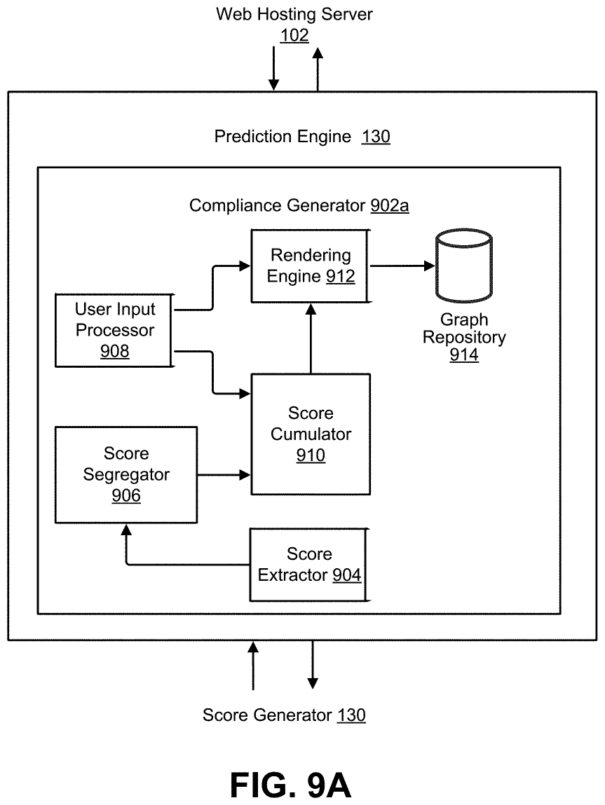

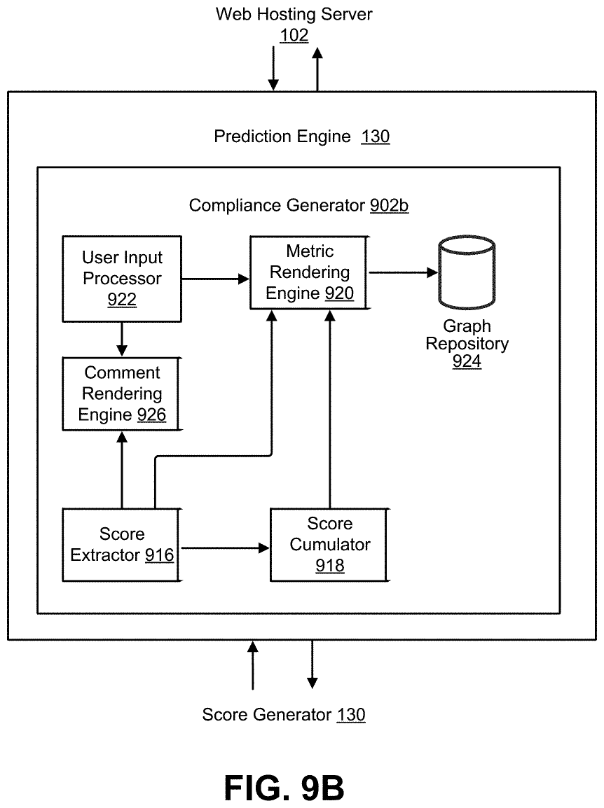

The scoring processor 810 may also determine first scores for each of the first subset of factors of the secondary test target. To this end, the factor identifying server 114b shares the first subset of factors along with values of the associated attributes with the score generator 130. The first factor counter 812 may receive the list of each of the first subset of factors and may initiate a counter for the first subset of factors. For a given factor, the scoring processor 810 may first determine a factor value for the factor based on a weighted average of the values of the attributes associated with the factor. The scoring processor 810 may then determine a first score for the factor in a similar manner as described above for the second scores. In an embodiment, the scoring processor 810 may generate multiple target specific first scores for the secondary test target. The scoring processor 810 may then share the multiple target specific first scores with the prediction engine 132. The prediction engine 132 thus receives the following scores from the score generator 130 with respect to the secondary test target: multiple target specific first scores and multiple target specific second scores for each factor. Based on these scores, the prediction engine 132 may generate a compliance metric for the secondary test target at the current testing stage. This is further explained in detail with reference to FIG. 9A.

In some embodiment, data required to generate multiple target specific first scores and multiple target specific second scores for each factor may be insufficient. In such cases, a notification or warning may be provided to the user to indicate insufficiency of date for making the score predictions with a high confidence score.

Now referring to the test target scorer 804, which may determine multiple scores for a primary test target. The test target scorer 804 may include a vector overlap determinator 824, an ML module 826, and a scoring processor 828. The vector overlap determinator 824 may determine an overlap between the test parameters of the primary test target and test parameter data represented by one or more of the matching test vectors 718. The test parameter data is the data based on which the primary test target was expected to be prepared. The vector overlap determinator 824 may additionally determine an overlap between the primary test target and one or more of the matching test vectors 718. It may be noted that each of the matching test vectors 718 are appended with following: Target parameter IDs and sources tags, i.e., parameter ‘D’ or target data ‘P.’

To this end, the vector overlap determinator 824 may include a vector extractor 830 and an overlap percentage calculator 832. The vector extractor 830 may first extract the test vectors 416 from the vector database 120 and the matching test vectors 718 from the vector matching server 122. The vector extractor 830 then identifies the source tags appended to each of the matching test vectors 718. Based on the source tags, the vector extractor 830 separates out a first set of matching test vectors from the matching test vectors 718. The first set of matching test vectors were generated based on the data retrieved from the profile databases 108. The overlap percentage calculator 832 may then determine a first overlap percentage between the test vectors 416 and the first set of matching test vectors. The first overlap percentage may determine and indicate the percentage of the test parameter data that has been captured in the input primary test target. High first overlap percentage may indicate that bulk of the test parameter data may have been mapped in the test parameters of the primary test target. In contrast, low first overlap percentage may indicate that bulk of the test parameter data may has been skipped from being captured in the primary test target. Thus, a high first overlap percentage may indicate a good quality primary test target from the perspective of exhaustive capturing of the test parameter data. The overlap percentage calculator 832 may then share the first overlap percentage with the scoring processor 828.

Based on the source tags, the vector extractor 830 additionally separates out a second set of matching test vectors from the matching test vectors 718. The second set of matching test vectors were generated based on the data retrieved from the parameter database 108a and/or the target parameter database 108b. The overlap percentage calculator 832 may then determine a second overlap percentage between the test vectors 416 and the second set of matching test vectors. The second overlap percentage may determine and indicate the percentage of data in the values of the testing parameters of the secondary test target that has already been matched with the values of the testing parameters of earlier tested similar test targets. High second overlap percentage may indicate that bulk of the test parameter data has already been captured in existing test parameters of test targets. Thus, in this case, the primary test target may have low entropy when compared to the existing test parameters of similar test targets. In contrast, low second overlap percentage may indicate that bulk of test parameters of the secondary test target is new and has not been matched in any test target. The overlap percentage calculator 832 may then share the second overlap percentage with the scoring processor 828.

In some embodiments, in case of low second overlap percentage, the overlap percentage calculator 832 may also identify a set of first test parameters of the primary test target that contribute to the higher matching. The overlap percentage calculator 832 may subsequently assign higher weights to each of the set of first sections. This information may be shared with the prediction engine 132, which may then highlight each of the set of first test parameters. In a similar manner, in case of high second overlap percentage, the overlap percentage calculator 832 may identify a set of test parameters of the primary test target that contribute to the lower matching. The overlap percentage calculator 832 may subsequently assign lower weights to each of the set of first sections. This information may be shared with the prediction engine 132, which may then highlight each of the set of second test parameter s, in order to differentiate them from the set of first test parameter s that contribute to higher matching.

The scoring processor 828 receives the first overlap percentage and the second overlap percentage from the overlap percentage calculator 832. Based on this, the scoring processor 828 may determine a first score and a second score for the primary test target. The first score is determined based on the first overlap percentage. The scoring processor 828 may assign the first score, such that, when the first overlap percentage is between 90-100, a score of ‘1’ is assigned. On the other hand, when the first overlap percentage is between 0-10, a score of ‘10’ is assigned. The scores may be on a scale of 1 to 10, such that, ‘1’ is the highest score, while ‘10’ is the lowest score. In contrast, the scoring processor 828 may assign the second score, such that, when the second overlap percentage is between 90-100, a score of ‘10’ is assigned and when the second overlap percentage is between 0-10, a score of 1′ is assigned. Thus, a high second score indicates high entropy, while a low second score indicates low entropy. The scoring processor 828 may share the first score and the second score for the primary test target with the prediction engine 132.

The ML module 826 may determine a third score for the primary test target. The third score may indicate conformance of the primary test target with various legal and statutory requirement of the industry standards associated with the primary test target, for example, the Semiconductor Equipment and Materials International (SEMI). To this end, the ML module 826 includes an evaluation rules engine 834, an ML algorithm engine 836, and a factor identifier 838. The evaluation rules engine 834 may include a plurality of evaluation rules, which may correspond legal and statutory requirement at multiple standard institutes. In some embodiments, for each jurisdiction, the evaluation rules engine 834 may store evaluation rules separately. By way of an example, an evaluation rule may correspond to “terminology” and the “test methods”. Thus, the evaluation rule may ensure that the primary test target sufficiently comply with the requirements of the standards. The evaluation rules may be applied on the test vectors 416 generated for the input primary test target. In an embodiment, the test vectors 416 may include separate test vectors for each of the primary test target. Thus, the evaluation rules may be applied on the test vectors generated for two or more test parameters. By way of an example, for terminology, the test vectors generated for the test parameters may be compared with the test vectors generated for a standard reference. To comply with the terminology requirement, the overlap of the test vectors generated for the test parameters should be 100% with the test vectors generated for the standard reference. By way of another example, an evaluation rule may correspond to determining whether the terminology for parts of the test target is similar to that mentioned with respect to the standard reference or not. To ensure compliance, the test vectors generated for the primary test target may be compared with the test vectors generated for the standard reference. The overlap should be as close to zero % as possible. By way of yet another example, another evaluation rule may be to ensure that each the test methods are in accordance with the standards. Conformance with these evaluation rules ensure that, after the primary test target has been fabricated, tested and packaged with minimum deviations from the standard reference provided by the standard institutes.

Moreover, one or more ML algorithms may also be trained to evaluate the testing parameters of the primary test target based on one or more evaluation rules that are stored in the evaluation rules engine 834. The one or more ML algorithms may be stored in the ML algorithm engine 836. An ML algorithm may be trained based on the deviations of the test parameters from the standards of the other test targets. By way of an example, these deviations from the standard values, rejections or testing failures may be used to train the ML algorithm. The ML algorithm thus trained may be able to identify similar issues in the primary test target. Additionally, the ML algorithm may be trained to identify process requirements and mechanisms to overcome these deviations and/or testing failures. This training may be performed based on the response to the testing of the other test targets, their test parameter values and the outcome of the testing procedures. Thus, the ML algorithm may not only be able to identify issues in the outcomes of the training results of the primary test target, but may also be able to suggest the required modifications in order to avoid any such deviation or rejection during testing of the primary test target after it undergoes testing.

As discussed before, each evaluation rule in the evaluation rules engine 834 may correspond to a legal or statutory requirement. Thus, for each such legal or statutory requirement a factor may be defined and then mapped to an evaluation rule. The mapping between different factors and the associated evaluation rules may be stored in the factor identifier 838. Example of factors may include, but are not limited to “Terminology,” “Test Methods,” “Specifications,” “Guidelines,” “Procedures.” Once the evaluation rules corresponding to each of these factors have been executed on the primary test target by the ML algorithm engine 836, values for each of these factors are determined. The value may be representative of degree of compliance with a given evaluation rule. By way of an example, if the ML algorithm trained to execute evaluation rule for checking “Terminology” results in a number of issues, the value of the corresponding factor may be very low.

In addition to determining values for each of these factors, weights may also be assigned to these factors based on their degree of relevance. By way of an example, the factors: “Test Methods” and “Specifications” may be given the highest weightage, while “terminology” may be given lowest weightage. Once the values and weightages for each of the factors has been determined, the ML algorithm engine 836 shares these with the scoring processor 828, which determines a third score for the primary test target based on a weighted average of the factor values. The scoring processor 828 shares the third score along with the first and the second scores with the prediction engine 132. The prediction engine 132 then generates a compliance metric for the primary test target, such that, the compliance metric is a function of the first, second, and third scores.

FIGS. 9A and 9B illustrate the prediction engine 132 that include a compliance generator 902a configured to generate a compliance metric for a secondary test target and a compliance generator 902b configured to generate the compliance metric for a primary test target, according to an embodiment of the present disclosure.

The compliance generator 902a may include a score extractor 904 that may extract multiple target specific first scores and multiple target specific second scores. The score extractor 904 may extract these scores for each factor, such that, the multiple target specific first scores are extracted for the first subset of factors (that are available), while the multiple target specific second scores are extracted for the second subset of factors (that are unavailable). A score segregator 906 may then segregate the extracted scores based on the factors and the targets and may maintain a table for the same. By way of an example, for each factor a separate table may be maintained. In that table, based on the various targets, scores may be separately stored. Thus, the score segregator 906 may have multiple such tables based on the number of factors.

A user may provide an input through a GUI rendered on the user device 104. The input may be received and processed by a user input processor 908. Based on the user input, the user input processor 908 may instruct a score cumulator 910 to extract specific scores for specific targets from the score segregator 906. By way of an example, the user may want to determine score of the secondary test target for various factors with “Space” as the target. The score cumulator 910 may accordingly extract the relevant scores. The relevant scores are then shared with a rendering engine 912 that may display a compliance metric based on the user input. The rendering engine 912 may be communicatively coupled to a graph repository 914, which may include various graphics that may be used to display the compliance metric.

When the user does not provide any specific input as to specific factors and targets, the rendering engine 912 may render a compliance metric for the secondary test target at the current testing stage. The compliance metric is a function of the multiple target specific first scores and the multiple target specific second scores extracted for each factor. By way of an example, the compliance metric may include four quadrants, such that, each quadrant represents score of the secondary test target for a specific target. The compliance metrics rendered on the GUI may be interactive, such that, inputs received from the user for modification of the compliance metric may be processed by the user input processor 908. Accordingly, the user input processor 908 may instruct the rendering engine 912 to modify the compliance metric.

The compliance metric generator 902b depicted in FIG. 9B includes a score extractor 916 that may extract the first score, the second score, and the third score from the test target scorer 804. The score extractor 916 may share the first score, the second score, and the third score with a score cumulator 918, which may determine a cumulative score for the primary test target. The cumulative score, for example, may be determined based on a simple average. Alternatively, the cumulative score may be determined based on a weighted average of the first, second, and third scores. The weights may either be system defined or may be assigned or modified by a user. The score cumulator 918 may thus store the cumulative score along with the first, second, and the third scores. Based on these scores, a metric rendering engine 920 may render a compliance metric on the GUI. The compliance metric may display the cumulative score for the primary test target, along with the first, second, and third scores. A user may thus be able to determine compliance of the primary test target based on various test parameters of evaluation. For example, a high first score may indicate that the primary test target satisfies maximum of the test parameters, a high second score may indicate that the primary test target satisfies maximum of the target parameters, and a high third score may indicate that the primary test target satisfies most of the evaluation rules and may thus be less rejected/failed during testing. Since the compliance metric is interactive, the user may provide inputs that may be processed by a user input processor 922. Based on processing of the inputs, the user input processor 922 may instruct the metric rendering engine 920 to modify graphics associated with the compliance metric. The metric rendering engine 920 may modify the graphics based on data or libraries available in a graph repository 924.

The score extractor 916 may additionally extract information from the ML algorithm engine 836 with regards to values determined for various factors and issues identified in the primary test target while executing various evaluation rules on the primary test target. The score extractor 916 may share this information with a comment rendering engine 926. The comment rendering engine 926 may process the results of the testing of the primary test target and may highlight or add comments to specific values or sections of the test parameters of the primary test target. These comments or highlights may indicate to a user that these specific test parameters have some issues, which require attention before the test target goes into the next testing stage or is assembled into a product. The comment rendering engine 926 may additionally provide comments as to the corrective actions required to be taken in order to fix these issues.

The score extractor 916 may also extract information from the overlap percentage calculator 832 with regards to specific test parameters of the primary test target that have high score and low score, when compared to existing test targets. The score extractor 916 may share this information with the comment rendering engine 926. The comment rendering engine 926 may process the primary test target and may highlight the values of the test parameters of the primary test target that have high score with a first predefined color and may highlight the sections within the primary test target that have low score with a second predefined color.

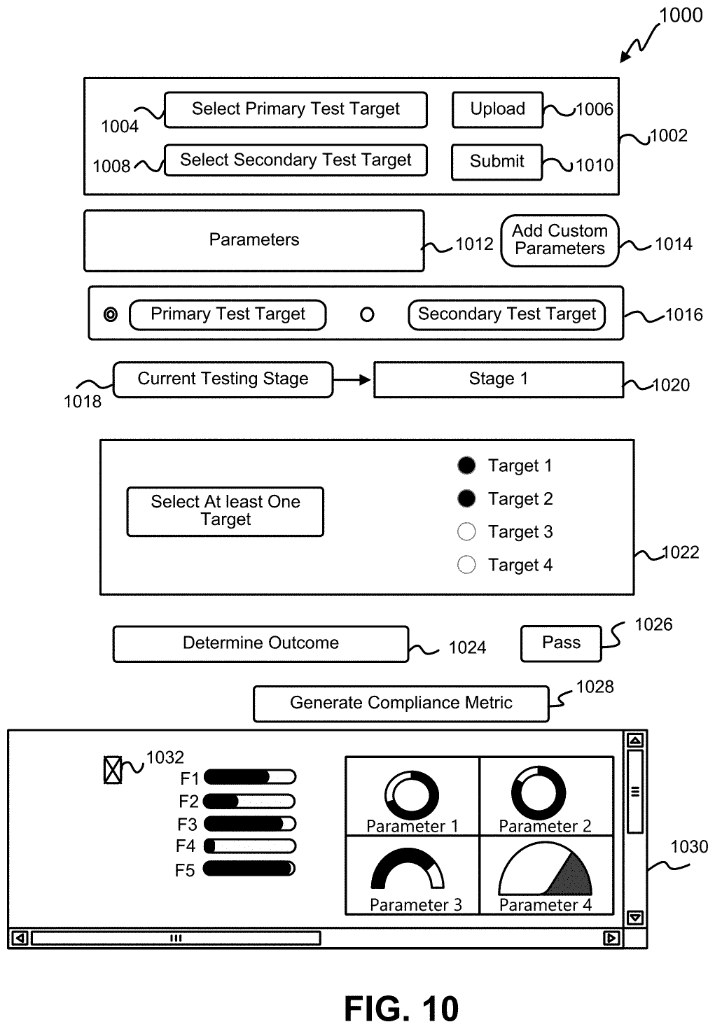

FIG. 10 illustrates a Graphical User Interface (GUI) 1000 associated with the compliance prediction system 100, according to an exemplary embodiment of the present disclosure. Various elements and sections depicted in the GUI 1000 are merely exemplary and are illustrated for the ease of depiction. The GUI 1000 may include additional elements and sections that are not shown in the FIG. 10. Moreover, multiple variations and combinations of the elements and sections are within the scope of the invention. The GUI 1000 may be provided by the compliance prediction system 100 on the user device 104, via the web hosting server 102. The GUI 1000 includes a test target selection field 1002 that is used to provide details associated with a secondary test target and/or a primary test target. The test target selection field 1002 includes a button 1004, which on activation allows a user to provide details of the primary test target stored on the user device 104. The user may provide the details of the secondary test target and/or the primary test target in the PDF format. Thereafter, the user may activate an upload button 1006 in order to upload the PDF file to the compliance prediction system 100. Alternatively, the user may enter details associated with the secondary test target through a text field 1008. In case of the secondary test target, the details, for example, may include, but are not limited to test parameters, specifications, tolerance, package size, values, and/or testing methods. In case of the primary test target, the details, for example, may include, but are not limited to process and target parameters, material, and/or wafer size of the primary test target. The user may thereafter activate a submit button 1010 in order to upload the details to the compliance prediction system 100.

On receiving the details associated with the secondary test target and/or the primary test target, the compliance prediction system 100 may determine a set of parameters that may be listed in a parameter field 1012. The set of parameters, for example, may include, but are not limited to process parameters, material, size, shape, thickness, and/or packaging. The type of parameters that are identified and listed in the parameter field 1012 may vary based on whether the user has provided a secondary test target or a primary test target. Additionally, when the user has provided a secondary test target, type of attributes may vary based on a current testing stage of the secondary test target. In addition to the set of parameters, the user may add custom parameters by pressing a button 1014. This may enable the user to add custom parameters in the parameter field 1012. Custom attributes, for example, may include, but are not limited to product name, type of technology, target, target parameters, or product line.

The GUI 1000 may include a field 1016 that may be used to specify to the compliance prediction system 100, whether the provided details are of the secondary test target or the primary test target. Radio buttons, for example, may be rendered in order to enable this selection. When the user has provided a secondary test target and has specified the same through the field 1016, the compliance prediction system 100 may retrieve testing history of the secondary test target based on the details and may identify the current testing stage of the secondary test target. Fields 1018 and 1020 may then be used to indicate and display the current testing stage of the secondary test target. In case, the compliance prediction system 100 is not able to identify the current testing stage, a user may manually enter the current testing stage via the field 1020.

The GUI 900 further includes a target selection field 1022 that may allow the user to select one or more targets, based on which a compliance metric for the secondary test target and/or the primary test target may be determined. If the user does not select any target, the compliance prediction system 100 selects all the targets by default to determine the compliance metric. In other words, the compliance metric in this case may be target independent. Once the user has made a selection of the one or more targets in the target selection field 1022, the user may then press a button 1024 to determine an outcome for the secondary test target and/or the primary test target, which may be displayed in a section 1026.

A button 1028 may also be provided to generate the compliance metric for the secondary test target and/or the primary test target. In response to activation of the button 1028, the compliance prediction system 100 may generate the compliance metric and may display a preview of the compliance metric in a field 1030. The compliance metric with respect to the test parameters is displayed in the field 1030 may correspond to a secondary test target. A button 1032 may be provided within the field 1030 to open the compliance metric in a new window, in order to enable the user to clearly view the compliance metric and interact with the same.

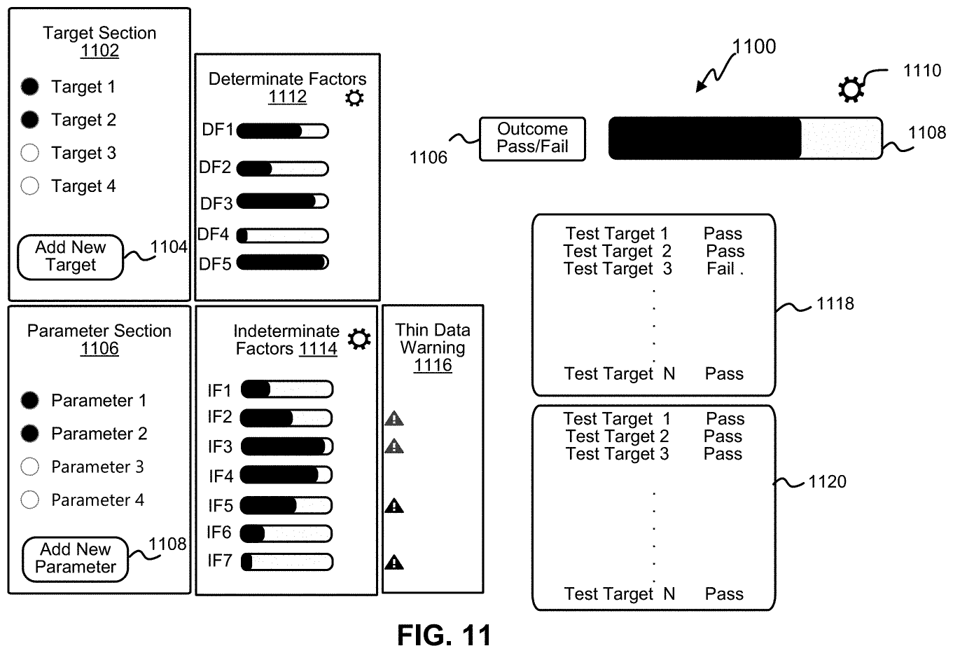

FIG. 11 illustrates a Graphical User Interface (GUI) 1100 associated with the compliance prediction system 100 configured to render compliance metric for a secondary test target, according to an exemplary embodiment of the present disclosure. Various elements and sections depicted in the GUI 1100 are merely exemplary and are illustrated for the ease of depiction. The GUI 1100 may include additional elements and sections that are not shown in the FIG. 11. Moreover, multiple variations and combinations of the elements and sections are within the scope of the invention. The GUI 1100 may be provided by the compliance prediction system 100 on the user device 104, via the web hosting server 102.

The GUI 1100 may include a target section 1102 that may enable a user to select one or more targets based on which compliance metric for the secondary test target is to be rendered. As depicted, in the target section 1102, the following targets are selected: target 1, target 2, target 3, and target 4. In case the user may want to add a new target that is not already listed, the user may activate a button 1104. In response to user selection of the targets in the target section 1102, fields 1106 and 1108 may be rendered to display an overall outcome for the secondary test target and/or the primary test target. The user may change the graphics used to display the overall score by clicking on a settings button 1110.

Additionally, the GUI 1100 may render scores for Available or Determinate Factors in the secondary test target as determined by the compliance prediction system 100 in a section 1112. Similarly, scores for Unavailable or Indeterminate Factors may be rendered in a section 1114 and thin data warning (if applicable) may be displayed in a section 1116. The scores displayed in sections 1112 and 1114 may change based on targets selected by the user. Additionally, the user may change the graphics used to display the scores by clicking on a settings buttons (similar to the settings button 1110) provided therein. The GUI 1100 may also display target wise outcomes (either pass or fail in testing) for the test targets by way of a graph 1118, which includes list, such that, outcomes of each of the test targets is displayed for a selected target. A user may interact with the graph 1118 to retrieve detailed information for each target specific score.

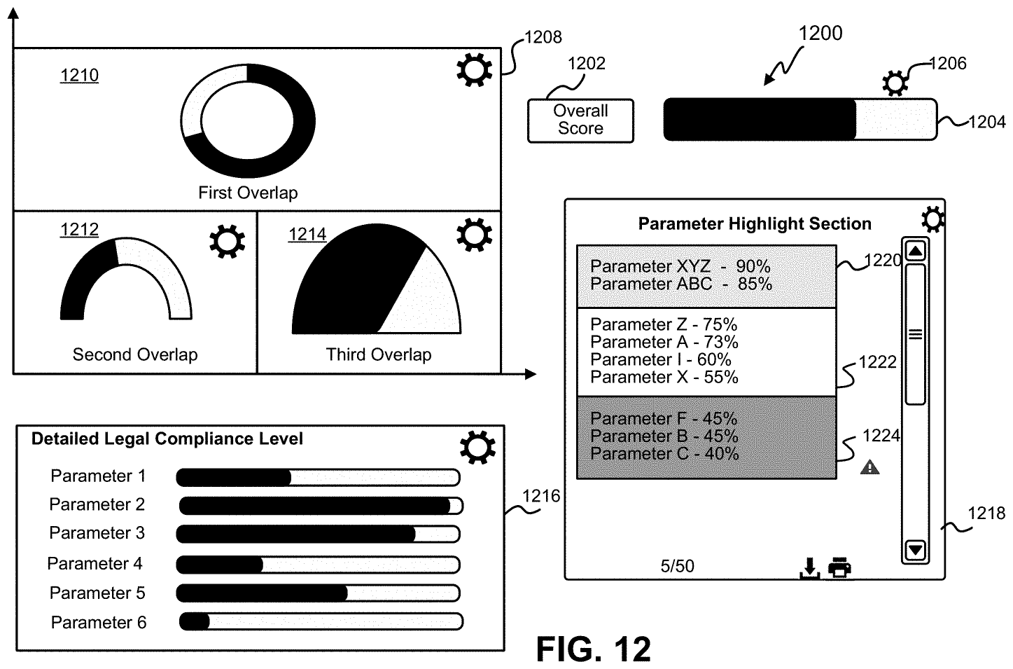

FIG. 12 illustrates a Graphical User Interface (GUI) 1200 associated with the compliance prediction system 100 configured to render the compliance metric for a primary test target, according to an exemplary embodiment of the present disclosure. Various elements and sections depicted in the GUI 1200 are merely exemplary and are illustrated for the ease of depiction. The GUI 1200 may include additional elements and sections that are not shown in the FIG. 12. Moreover, multiple variations and combinations of the elements and sections are within the scope of the invention. The GUI 1200 may be provided by the compliance prediction system 100 on the user device 104, via the web hosting server 102.

The GUI 1200 may include fields 1202 and 1204 that may be displayed to render an overall score for the primary test target. The user may change the graphics used to display the overall score by clicking on a settings button 1206. The overall score may be divided into three scores and may be displayed using a graph 1208, which may display scores for test parameter value overlap in a score section 1210, target parameter overlap in a score section 1212, and/or legal/statutory compliance overlap in a score section 1214. In each of these sections 1210, 1212, and 1214, a settings button (similar to the settings button 1206) may be provided to change the graphics used to display the scores.

The user may click on the score given in the section 1214 (i.e., the legal compliance score), in response to which, detailed legal compliance scores may be displayed in a section 1216. A settings button (similar to the settings button 1206) may be provided in the section 1216, which may be used to change the graphics used to display the detailed legal compliance scores. In a similar manner, when the user clicks on the score given in the section 1212 (i.e., the first overlap score), a section 1218 may be rendered on the GUI 1200. In the section 1218, various sections display the test parameters and their overlap percentages of the primary test target with the values of the test parameters of the standard test targets. The sections may be highlighted using different colors and messages to indicate whether a particular section of the primary test target has high overlap or low overlap. By way of an example, in the section 1218 as depicted in FIG. 12, a section 1220 with light grey colored highlighting has high overlap, a section 1222 with no highlight has medium overlap, while a section 1224 with dark grey colored highlighting has low overlap. The low entropy in the section 1224 is also indicated by rendering a warning sign adjacent to the section 1224. In the section 1218, options to print or download the results of the test target with overlap highlights may also be provided. Additionally, the current page number being of the primary test target being viewed in the section 1218 may also be depicted.

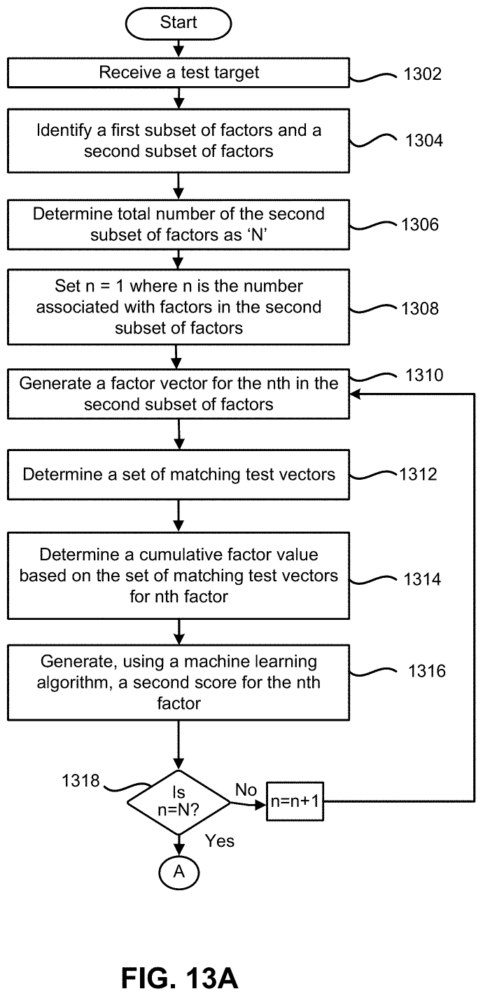

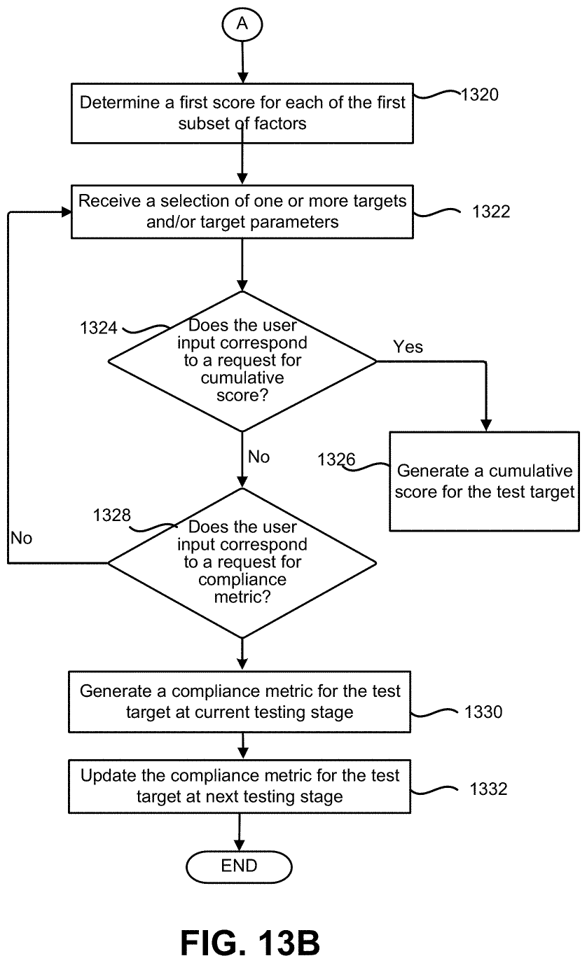

FIGS. 13A and 13B is a flowchart of a method 1300 for generating compliance metrics for test targets, according to an embodiment of the present disclosure. At step 1302, details of a test target are received. At step 1304, a first subset of factors and a second subset of factors are identified from a set of factors. The first subset of factors are available at a current testing stage of the test target and the second subset of factors are unavailable at the current testing stage. At step 1306, the total number of second subset of factors are determined as N. At step 1308, n is set as 1, such that, n represent the current number of a factor from the second subset of factors that is being processed. At step 1310, a factor vector is determined for the current factor. At step 1312, a set of matching test vectors are determined from a plurality of factor vectors for the current factor. At step 1314, a cumulative factor value is determined for the current factor, based on the set of matching factor vectors. At step 1316, a second score is generated for the current factor based on the cumulative factor value and the set of matching test vectors, using an associated ML algorithm. At step 1318, a check is performed to determine whether the current value of ‘n’ is equal to ‘N,’ or not. When the current value is not equal to ‘N,’ the value of ‘n’ is incremented by 1 and the control moves to step 1310. However, if the current value of ‘n’ is equal to ‘N,’ the control moves at step 1320.

At step 1320, a first score is determined for each of the first subset of factors. At step 1322, a user input and/or a user selection of one or more targets and/or target parameter is received. At step 1324, a check is performed to determine whether the user input correspond to a request for a cumulative score. If yes, at step 1326, a cumulative score is generated for the test target. Referring back to step 1324, when the user input does not correspond to the request for the cumulative score, a check is performed at step 1328 to determine if the user input correspond to a request for a compliance metric. If the request corresponds to the compliance metric, a compliance metric is generated for the test target at the current testing stage for the one or more targets based on the first score and the second scores, at step 1330. Referring back to step 1328, if the request does not correspond to the compliance metric, the control moves to step 1322. At step 1332, the compliance metric is updated as the test target moves to the next testing stage. Generation of the compliance metric for the secondary test target has already been explained with reference to FIG. 1 to FIGS. 9A and 9B.

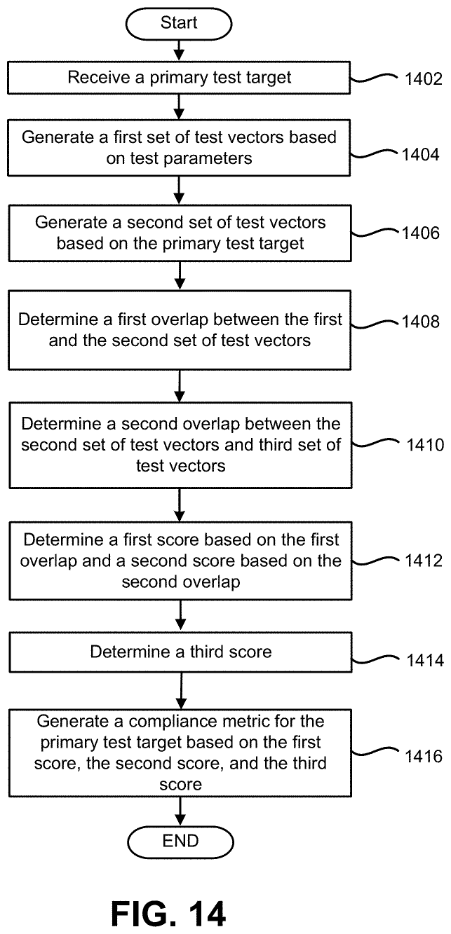

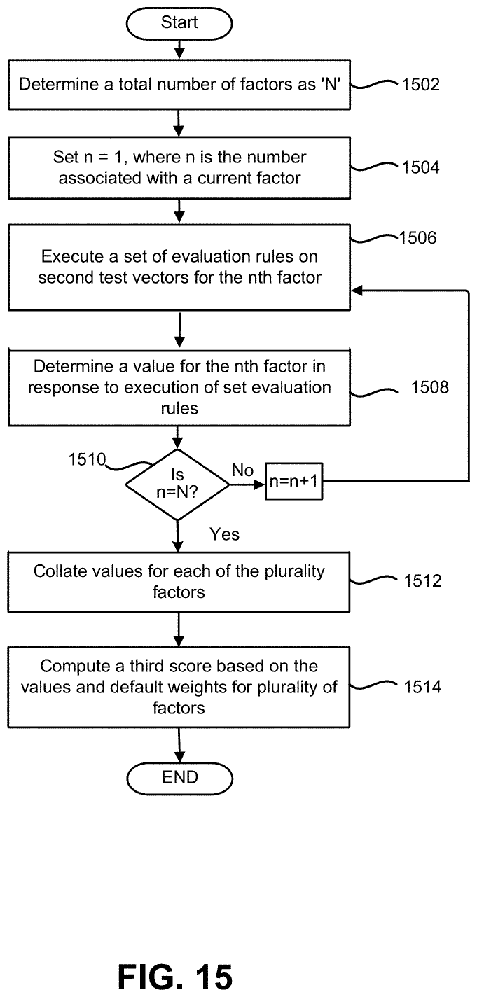

FIG. 14 is a flowchart of a method 1400 for generating a compliance metric for primary test targets, according to an embodiment of the present disclosure. At step 1402, details of a primary test target are received. At step 1404, a first set of test vectors is generated for test parameters associated with the test target. At step 1406, a second set of test vectors are generated based on actual testing parameters of the test target. At step 1408, a first overlap percentage between the first and second set of test vectors is determined. At step 1410, a second overlap percentage between the second set of test vectors and a third set of test vectors generated for a plurality of test targets is determined. At step 1412, a second score for the primary test target is determined based on the second overlap percentage. At step 1414, a third score is determined for the primary test target. Determination of the third score is further explained in detail in conjunction with FIG. 15. At step 1416, a compliance metric for the primary test target is generated based on the first score, the second score, and the third score. Generation of the compliance metric for the primary test target has already been explained with reference to FIG. 1 to FIGS. 9A and 9B.

FIG. 15 is a flowchart of a method 1500 for generating a third score for a primary test target, according to an embodiment of the present disclosure. At step 1502, the total number of plurality of factors is determined as ‘N.’ At step 1504, the value of ‘n’ is set as 1, such that, n represents the current factor within the plurality of factors. At step 1506, a machine learning algorithm executes instruction corresponding to a set of evaluation rules on a second set of test vectors (generated for the primary test target) for the current factor. At step 1508, a value for the current factor is determined in response to execution of the set of evaluation rules. At step 1510, a check is performed to determine whether the current value of ‘n’ is equal to ‘N’ or not. If the current value of ‘n’ is not equal to ‘N,’ the value of ‘n’ is incremented by 1 and the control moves to step 1506. However, if the current value of ‘n’ is equal to ‘N,’ values for each of the plurality of factors is collated at step 1512. At step 1514, a check is performed to determine if a user has assigned weights to the plurality of factors. If yes, a third score is computed based on the values and the user assigned weights for the plurality of factors, at step 1516. However, if the user has not assigned weights to the plurality of factors, the third score is computed based on the values and the default weights for the plurality of factors, at step 1518. Determination of a third score for the primary test target has already been explained with reference to FIGS. 8A and 8B.

Specific details are given in the above description to provide a thorough understanding of the embodiments. However, it is understood that the embodiments may be practiced without these specific details. For example, circuits may be shown in block diagrams in order not to obscure the embodiments in unnecessary detail. In other instances, well-known circuits, processes, algorithms, structures, and techniques may be shown without unnecessary detail in order to avoid obscuring the embodiments.

Implementation of the techniques, blocks, steps and means described above may be done in various ways. For example, these techniques, blocks, steps and means may be implemented in hardware, software, or a combination thereof. For a hardware implementation, the processing units may be implemented within one or more application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, other electronic units designed to perform the functions described above, and/or a combination thereof.

Also, it is noted that the embodiments may be described as a process which is depicted as a flowchart, a flow diagram, a swim diagram, a data flow diagram, a structure diagram, or a block diagram. Although a depiction may describe the operations as a sequential process, many of the operations can be performed in parallel or concurrently. In addition, the order of the operations may be re-arranged. A process is terminated when its operations are completed, but could have additional steps not included in the figure. A process may correspond to a method, a function, a procedure, a subroutine, a subprogram, etc. When a process corresponds to a function, its termination corresponds to a return of the function to the calling function or the main function.

Furthermore, embodiments may be implemented by hardware, software, scripting languages, firmware, middleware, microcode, hardware description languages, and/or any combination thereof. When implemented in software, firmware, middleware, scripting language, and/or microcode, the program code or code segments to perform the necessary tasks may be stored in a machine readable medium such as a storage medium. A code segment or machine-executable instruction may represent a procedure, a function, a subprogram, a program, a routine, a subroutine, a module, a software package, a script, a class, or any combination of instructions, data structures, and/or program statements. A code segment may be coupled to another code segment or a hardware circuit by passing and/or receiving information, data, arguments, parameters, and/or memory contents. Information, arguments, parameters, data, etc. may be passed, forwarded, or transmitted via any suitable means including memory sharing, message passing, token passing, network transmission, etc.

For a firmware and/or software implementation, the methodologies may be implemented with modules (e.g., procedures, functions, and so on) that perform the functions described herein. Any machine-readable medium tangibly embodying instructions may be used in implementing the methodologies described herein. For example, software codes may be stored in a memory. Memory may be implemented within the processor or external to the processor. As used herein the term “memory” refers to any type of long term, short term, volatile, nonvolatile, or other storage medium and is not to be limited to any particular type of memory or number of memories, or type of media upon which memory is stored.

Moreover, as disclosed herein, the term “storage medium” may represent one or more memories for storing data, including read only memory (ROM), random access memory (RAM), magnetic RAM, core memory, magnetic disk storage mediums, optical storage mediums, flash memory devices and/or other machine readable mediums for storing information. The term “machine-readable medium” includes, but is not limited to portable or fixed storage devices, optical storage devices, and/or various other storage mediums capable of storing that contain or carry instruction(s) and/or data.

While the principles of the disclosure have been described above in connection with specific apparatuses and methods, it is to be clearly understood that this description is made only by way of example and not as limitation on the scope of the disclosure.

1. A compliance testing system for predicting an outcome of a compliance testing of a test target, the compliance testing system comprising:
at least one processor;
at least one memory coupled with the at least one processor, wherein the at least one processor and the at least one memory are configured to:
identify determinate factors and indeterminate factors from a set of factors associated with a current testing stage of the compliance testing system, wherein a first factor value for each of the determinate factors is available and a second factor value for each of the indeterminate factors is unavailable for the current testing stage;
generate a test vector for each of the indeterminate factors, wherein the test vector for each of the indeterminate factors is generated based on a set of parameters associated with a corresponding indeterminate factor;
determine a set of matching test vectors for each of the indeterminate factors based on the test vector, wherein the set of matching test vectors are determined using data extracted from at least one profile model;
determine a cumulative factor value for each of the indeterminate factors based on the set of matching test vectors, wherein each matching test vector within the set of matching test vectors comprises a test value, the test value is determined based on a weighted average of values of the parameters;
determine, for each of the determinate factors, a first outcome corresponding to the at least one profile model;
generate, for each of the indeterminate factors using a corresponding machine learning algorithm, a second outcome based on the cumulative factor value and the set of matching test vectors extracted from the at least one profile model, wherein the at least one profile model corresponds to at least one target parameter; and
generate a compliance prediction at the current testing stage of the test target for the at least one target parameter based on the first outcome and the second outcome.

2. The compliance testing system for predicting the outcome of the compliance testing of the test target as recited in claim 1, wherein the test target is a microelectronic circuit.

3. The compliance testing system for predicting the outcome of the compliance testing of the test target as recited in claim 1, wherein the at least one processor and the at least one memory are further configured to:
identify insufficiency of data required to determine the second outcome of a factor within the indeterminate factors; and
compute a confidence level associated with the second outcome of the factor, based on a magnitude of insufficiency of the data.

4. The compliance testing system for predicting the outcome of the compliance testing of the test target as recited in claim 3, wherein identifying the insufficiency, the at least one processor and the at least one memory are further configured to:
compare a number of test vectors in the set of matching test vectors with a first pre-determined threshold; and
compare a variance amongst the set of matching test vectors with a second pre-determined threshold.

5. The compliance testing system for predicting the outcome of the compliance testing of the test target as recited in claim 4, wherein the magnitude of insufficiency is determined based on at least one of a difference between the number of test vectors and the first pre-determined threshold or the difference between the variance and the second pre-determined threshold.

6. The compliance testing system for predicting the outcome of the compliance testing of the test target as recited in claim 1, wherein the at least one processor and the at least one memory are further configured to:
update the compliance prediction at each testing stage based on the current testing stage proceeding to a final testing stage; and
stack the compliance prediction along a timeline comprising a plurality of testing stages.

7. A method of predicting an outcome of a compliance testing of a test target, the method comprising:
identifying determinate factors and indeterminate factors from a set of factors associated with a current testing stage of the compliance testing, wherein a first factor value for each of the determinate factors is available and a second factor value for each of the indeterminate factors is unavailable for the current testing stage;
generating a test vector for each of the indeterminate factors, wherein the test vector for each of the indeterminate factors is generated based on a set of test attributes associated with a corresponding indeterminate factor;
determining a set of matching test vectors for each of the indeterminate factors based on the test vector, wherein the set of matching test vectors are determined using data extracted from at least one profile model;
determining a cumulative factor value for each of the indeterminate factors based on the set of matching test vectors, wherein each matching test vector within the set of matching test vectors comprises a test value, and the test value is determined based on a weighted average of values of the test attributes;
determining, for each of the determinate factors, a first outcome corresponding to the at least one profile model;
generating, for each of the indeterminate factors using a corresponding machine learning algorithm, a second outcome based on the cumulative factor value and the set of matching test vectors extracted from the at least one profile model, wherein the at least one profile model corresponds to at least one target parameter; and
generating a compliance prediction at the current testing stage of the test target for the at least one target parameter based on the first outcome and the second outcome.

8. The method of predicting the outcome of the compliance testing of the test target as recited in claim 1, wherein the outcome of the compliance testing is predicted for a microelectronic circuit.

9. The method of predicting the outcome of the compliance testing of the test target as recited in claim 7, further comprising:
identifying insufficiency of data required to determine the second outcome of a factor within the indeterminate factors; and
computing a confidence level associated with the second outcome of the factor, based on a magnitude of insufficiency of the data.

10. The method of predicting the outcome of the compliance testing of the test target as recited in claim 9, wherein the identifying the insufficiency comprises:
comparing a number of test vectors in the set of matching test vectors with a first pre-determined threshold; and
comparing a variance amongst the set of matching test vectors with a second pre-determined threshold.

11. The method of predicting the outcome of the compliance testing of the test target as recited in claim 10, wherein the magnitude of insufficiency is determined based on at least one of a difference between the number of test vectors and the first pre-determined threshold or the difference between the variance and the second pre-determined threshold.

12. The method of predicting the outcome of the compliance testing of the test target as recited in claim 7, further comprising:
updating the compliance prediction at each testing stage based on the current testing stage proceeding to a final testing stage; and
stacking the compliance prediction along a timeline comprising a plurality of testing stages.

13. The method of predicting the outcome of the compliance testing of the test target as recited in claim 7, wherein the first outcome and the second outcome are scores associated with the set of factors of the test target.

14. A compliance test system for generating a compliance prediction for a test target, the compliance test system comprising:
a vector generating server comprising a processor and memory with instructions configured to:
identify determinate factors and indeterminate factors from a set of factors associated with a current testing stage of the compliance test system, wherein a first factor value for each of the determinate factors is available and a second factor value for each of the indeterminate factors is unavailable for the current testing stage; and
generate a test vector for each of the indeterminate factors, wherein the test vector for each of the indeterminate factors is generated based on a set of parameters associated with a corresponding indeterminate factor;
a vector matching server comprising a processor and memory with instructions configured to:
determine a set of matching test vectors for each of the indeterminate factors based on the test vector, wherein the set of matching test vectors are determined using data extracted from at least one profile model;
a vector processing server comprising a processor and memory with instructions configured to:
determine a cumulative factor value for each of the indeterminate factors based on the set of matching test vectors, wherein each matching test vector within the set of matching test vectors comprises a test value, the test value is determined based on a weighted average of values of the parameters;
determine, for each of the determinate factors, a first outcome corresponding to the at least one profile model; and
generate, for each of the indeterminate factors using a corresponding machine learning algorithm, a second outcome based on the cumulative factor value and the set of matching test vectors extracted from the at least one profile model, wherein the at least one profile model corresponds to at least one target parameter; and
a prediction engine comprising a processor and memory with instructions configured to:
generate the compliance prediction at the current testing stage of the test target for the at least one target parameter based on the first outcome and the second outcome.

15. The compliance test system for generating the compliance prediction for the test target as recited in claim 14, wherein the test target is a microelectronic circuit.

16. The compliance test system for generating the compliance prediction for the test target as recited in claim 14, wherein the prediction engine is further configured to:
identify insufficiency of data required to determine the second outcome of a factor within the indeterminate factors; and
compute a confidence level associated with the second outcome of the factor, based on a magnitude of insufficiency of the data.

17. The compliance test system for generating the compliance prediction for the test target as recited in claim 16, wherein to identify the insufficiency, the prediction engine is further configured to:
compare a number of test vectors in the set of matching test vectors with a first pre-determined threshold; and
compare a variance amongst the set of matching test vectors with a second pre-determined threshold.

18. The compliance test system for generating the compliance prediction for the test target as recited in claim 17, wherein the magnitude of insufficiency is determined based on at least one of a difference between the number of test vectors and the first pre-determined threshold or the difference between the variance and the second pre-determined threshold.

19. The compliance test system for generating the compliance prediction for the test target as recited in claim 17, wherein the first outcome and the second outcome are scores associated with the set of factors of the test target.

20. The compliance test system for generating the compliance prediction for the test target as recited in claim 19, wherein the vector processing server is further configured to display the first outcome and the second outcome associated with the test target, and wherein the compliance prediction comprises an indication of whether the test target fails or passes a compliance test performed by the compliance test system.

21.-40. (canceled)
